(19) United States
(12) Patent Application Publication
(10) Pub. No.: US 2020/0341515 A1
(43) Pub. Date: Oct. 29, 2020

(54) Advanced Laptop Hardware and Software Architecture

(71) Applicant: MLY Technix Corp., Santa Clara, CA (US)

(72) Inventors: George MOSER, Santa Clara, CA (US); Binoy Joseph, San Jose, CA (US)

(21) Appl. No.: 16/504,474

(22) Filed: Jul. 8, 2019

Related U.S. Application Data
(60) Provisional application No. 62/920,449, filed on Apr. 29, 2019.

(51) Int. Cl. G06F 1/16; G06F 3/0488; H05K 7/14; H05K 5/02

(52) U.S. Cl. CPC G06F 1/1649; G06F 1/1618; G06F 1/1643; H05K 5/0226; G06F 3/04886; H05K 7/14; G06F 1/1681

(57) ABSTRACT

A laptop computer is provided having two display screens. A first display screen is attached to a base unit proximate a display screen edge closest to the laptop user via one or more hinges. A second display screen may be attached via a second set of hinges either to the first display screen or to the laptop base. A support structure may support the first display screen in an inclined position relative to the laptop base. The laptop computer may implemented application or operating system software to utilize one or more of the display screens as a virtual keyboard, and to allocate application workspaces and controls to differing display screens.

### FIELD OF THE INVENTION

The present invention relates in general to the computer field, and in particular, to portable computer hardware and software.

### SUMMARY

The present invention discloses novel hardware architectures for multiscreen laptop computers. It also discloses a new multi-screen oriented software methodology for application software and a new type of multi-screen oriented Operating System for laptop computers, which bring to life the major advantages of multi-screen laptop computers well beyond convenience and additional screen space with a new paradigm in software development at both application and operating system levels.

### BRIEF DESCRIPTION OF THE DRAWINGS

FIG. 1 is a perspective view of a prior art typical laptop computer

FIG. 2 is a perspective view of a prior art dual-screen laptop computer

FIG. 3 is a perspective view of a prior art dual-screen laptop computer with an adjustable secondary screen

FIG. 4 is a perspective view of a dual-screen laptop computer with two full-size adjustable displays, including an optional support structure for the secondary screen

FIG. 5 is a perspective view of a dual-screen laptop computer with two full-size adjustable displays, including an optional support structure for the secondary screen and a virtual keyboard on the secondary screen

FIG. 6 is a perspective view of a dual-screen laptop computer with two full-size adjustable displays, and with a virtual keyboard and a virtual touch pad on the secondary screen.

FIG. 7 is a schematic illustration of a methodology to increase the accuracy and reduce the input errors in a virtual keyboard.

FIG. 8 is a side elevation of a dual-screen laptop computer, illustrating an exemplary geometry for image quality optimization.

FIG. 9 is a side elevation of a dual full screen laptop enhanced with a deployable incline mechanism to incline the laptop base and improve viewing angle, shown in a stowed position.

FIG. 10 shows the deployable incline mechanism structure of FIG. 9 in a deployed position.

FIG. 11 shows a side view of a deployable incline mechanism for the laptop, in deployed position.

FIG. 12 shows a side view of a deployable incline mechanism that is substantially contained and concealed inside the laptop base housing when not deployed.

FIG. 13 is a perspective view of a multiscreen laptop computer with a partial size second display and a physical keyboard.

FIG. 14 is a perspective view of a multiscreen laptop computer illustrating a prop-up mechanism for the second screen.

FIG. 15 is a side view of a laptop computer with an incline mechanism in a deployed position.

FIG. 16 is a top perspective view of the D-panel of a multiscreen laptop.

FIG. 17 is a partial perspective view showing details of a multiscreen laptop incline mechanism.

FIG. 18 is a bottom perspective view of the incline mechanism of FIG. 17.

FIG. 19 is a rear bottom view of the D-panel, in accordance with the embodiment of FIG. 17.

FIG. 20 is a partial bottom perspective view of a D-panel with stylus compartment.

FIG. 21 is a perspective view of another embodiment of a multiscreen laptop with two screens and a keyboard.

FIG. 22 shows the previous embodiment with screens in a deployed position.

FIG. 23 shows the previous embodiment with screens in an aligned position.

FIG. 24 shows the previous embodiment with screens in a presentation mode.

FIG. 25 is a perspective view of another embodiment of a multiscreen laptop with two full-size screens.

FIG. 26 shows the previous embodiment with screens in a deployed position.

FIG. 27 shows the previous embodiment with screens in an aligned position.

FIG. 28 shows the previous embodiment with screens in a presentation mode.

FIG. 29 is a schematic block diagram of a prior art software application.

FIG. 30 is a schematic block diagram showing more details of a prior art software application.

FIG. 31 is a schematic block diagram illustrating a new software user interface.

FIG. 32 shows the new software user interface with reversed display roles.

FIG. 33 shows a prior art CAD software application user interface.

FIG. 34 shows a new software user interface as applied to a CAD application.

FIG. 35 shows a prior art software application user interface.

FIG. 36 shows the new software user interface and methodology applied to an office application.

FIG. 37 is a variation of the new software user interface and methodology of FIG. 36.

FIG. 38 shows a prior art single screen Operating System.

FIG. 39 shows the setup screen of a prior art single screen Operating System.

FIG. 40 shows the arrangement of displays in a prior art single screen Operating System.

FIG. 41 shows a setup screen of a Multiscreen Operating System.

FIG. 42 shows the arrangement of displays in a Multiscreen Operating System.

FIG. 43 shows another possible arrangement of displays in a Multiscreen Operating System.

FIG. 44 shows a setup screen in a Multiscreen Operating System.

FIG. 45 shows two aligned screen in a multiscreen laptop computer.

### DESCRIPTION OF THE INVENTION

There is an increasing need in the portable computer industry to increase the available display area in laptop computers to provide higher productivity, better functionality and a superior user experience, which can be achieved with multiple displays. The present invention discloses significant improvements in both hardware and software for a new generation of multi-display laptop computers.

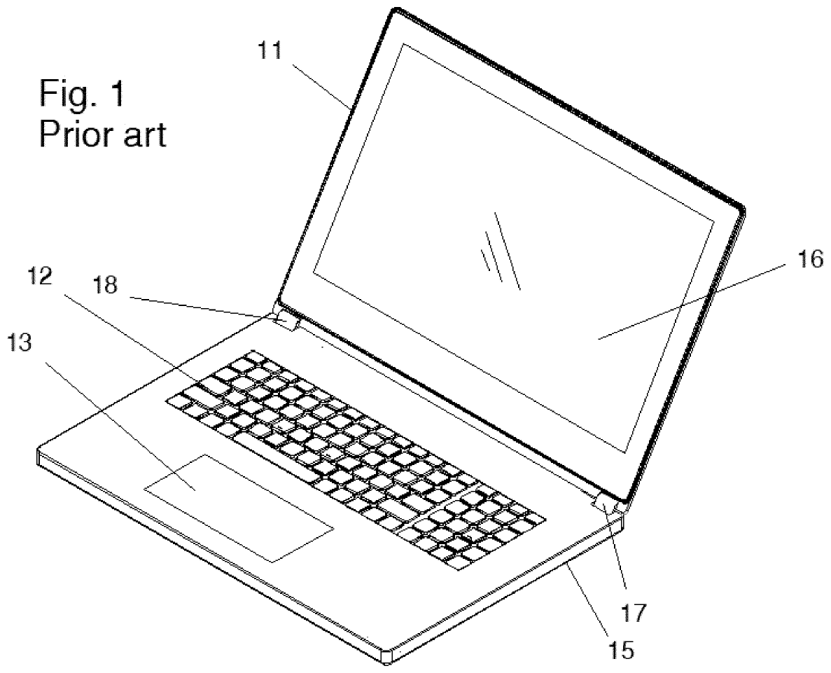

FIG. 1 (Prior art) shows a typical prior art laptop computer. This configuration includes base unit 15, which is rotatably connected to display unit 11 through hinges 17 and 18. The base unit 15 includes a keyboard 12 and a touchpad 13. The display unit 11 includes a display panel 16, typically an LCD screen. A limitation of this computer is the limited display area available (only the display shown as 16).

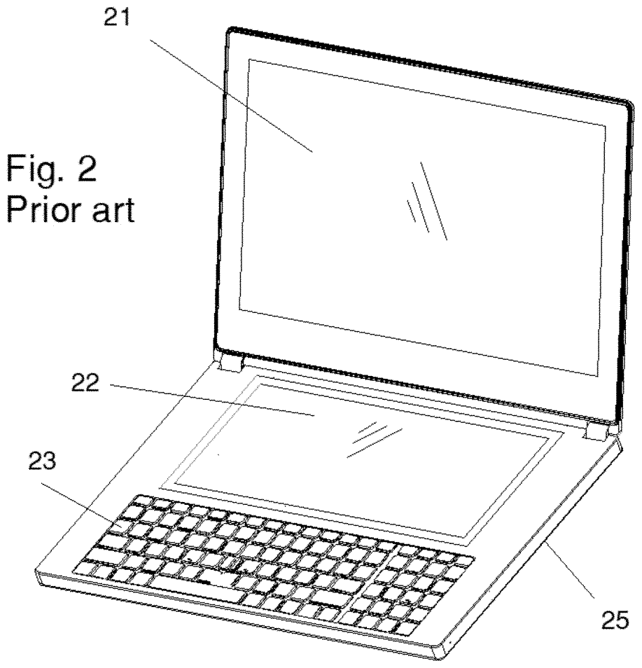

FIG. 2 (Prior art) shows the laptop computer from U.S. Pat. No. 9,501,097 (“the '097 Patent”), which shows a main screen 21 and a secondary screen 22. The secondary screen 22 is rotatably attached to the base 25 to allow the user to adjust the viewing angle of the secondary 22 screen (in addition to adjusting the viewing angle of the main screen 21, which is also rotatably attached to the base 25 through its own hinges). The hinges of the secondary screen 22 are not visible in FIG. 2 because in the shown embodiment said hinges are inside the base unit 25, not visible to the user.

Rotational adjustability of the secondary screen 22 is important because a completely horizontal, non-adjustable fixed position of the screen 22 would degrade the image quality for the user by not allowing the user to adjust the viewing angle for the second screen 22. A fixed horizontal secondary display 22 would also have the additional problem that it would likely reflect overhead lighting of a room in which the computer is used, further degrading the viewer's perceived image quality and the user experience.

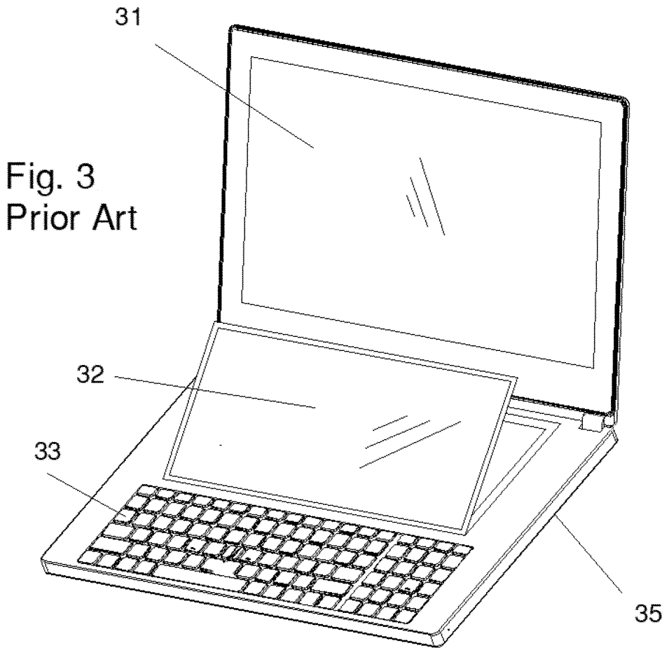

FIG. 3 (Prior art) shows that by rotating the secondary screen 32 of an embodiment illustrated in the '097 Patent about its hinges, a more favorable viewing angle can be achieved for secondary screen 32. The solution of the '097 Patent does provide true multitasking with dual screen functionality and a good image quality, but it also has complexities and cost issues associated with it, because attaching a hinged display to the base can be challenging, since the base is usually full of electronic components, battery and devices, making it difficult to find the space to house the secondary screen 32 and its hinges inside the base 35 without unduly increasing the total thickness of the laptop. A need remains in the industry for a simple and lower cost computer that will provide multiple screen capabilities and viewing angle adjustability for optimal image quality on both screens.

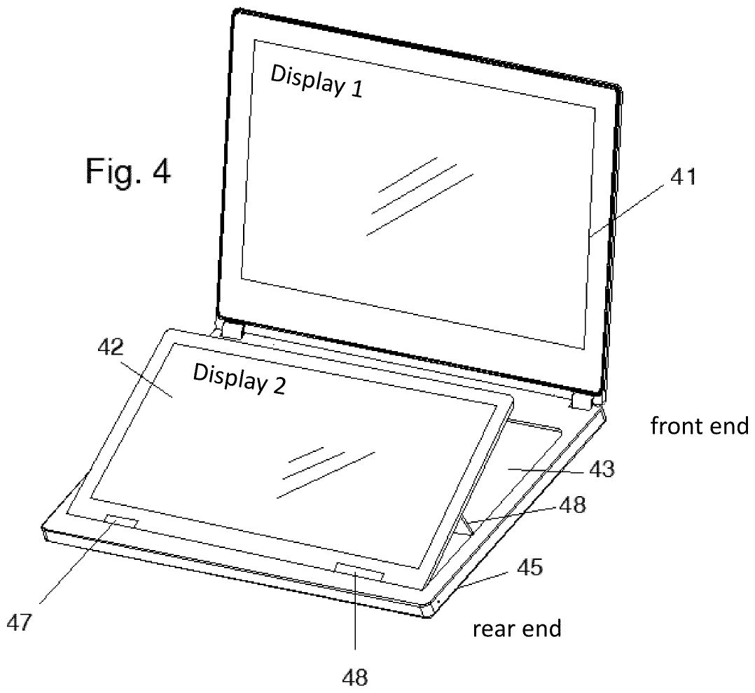

FIG. 4 shows one of the preferred embodiments of the present invention, which comprises a main display 41 rotatably attached to the laptop base 45; and a second large display 42 occupying substantially all or a majority of the available top area of the base 45. The second display 42 is rotatably attached to the laptop base 45 through hinges 47 and 48, positioned proximate a leading edge of second display 42 (i.e. an edge closest to the user during typical use of the laptop computer). Alternatively, the hinges 47 and 48 could be also designed to be hidden inside the base 45, not visible to the user. When the user wants to close the laptop, he can push down the second display 42 and fold it down into bay 43. Bay 43 provides a receptacle inside base 45 that securely houses the second display 42 in a non-deployed position. Absent in this embodiment is the keyboard of FIG. 3. In this embodiment, no space is dedicated to a physical keyboard.

FIG. 4 also shows an optional feature, a support structure 48 located behind display 42, which may consist basically of a plate, set of plates or beams that a user may deploy such that it or they are contacting both a back surface of second display 42, and a bottom surface of bay 43, thereby providing physical support to prop up second display 42. Typically, the support structure will extend between a portion of the display 42 that is spaced apart from the hinges connecting display 42 to base 45, and a portion of base 45 that is also spaced apart from the hinges connecting display 42 to base 45, thereby promoting support of display 42. In some embodiments, support structure 48 will be interposed between display 42 and base 45 at a position one-half or one-third of the distance from an edge of display 42 closest to user of the laptop computer, and an edge of display 42 furthest from the laptop user. Use of a support structure such as support structure 48 may be advantageous if the user is using touchscreen capabilities of display 42, or drawing on display 42 (whether with a stylus or via touch), to provide a more stable display surface on which the user may physically interact. The support structure 48 can be hinged to or otherwise attached to a back surface of display 42, the laptop base (e.g. a surface within bay 43), or both.

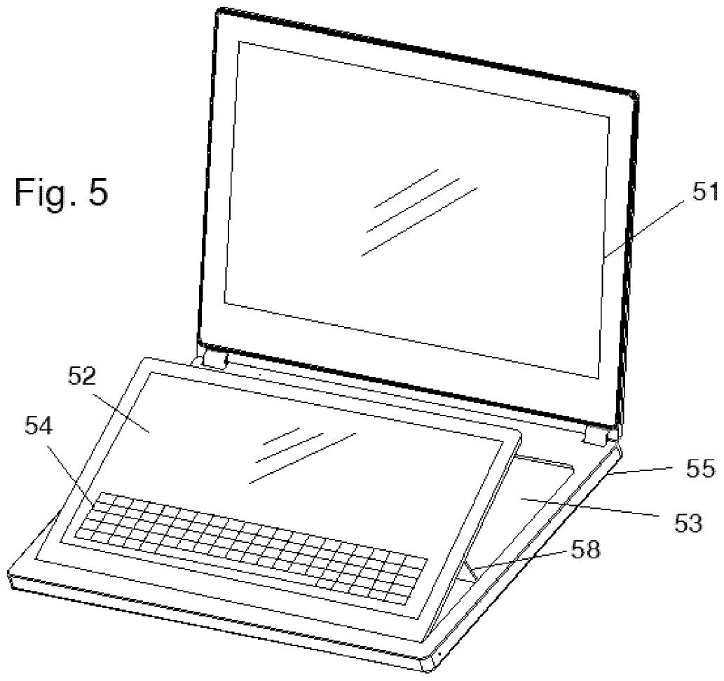

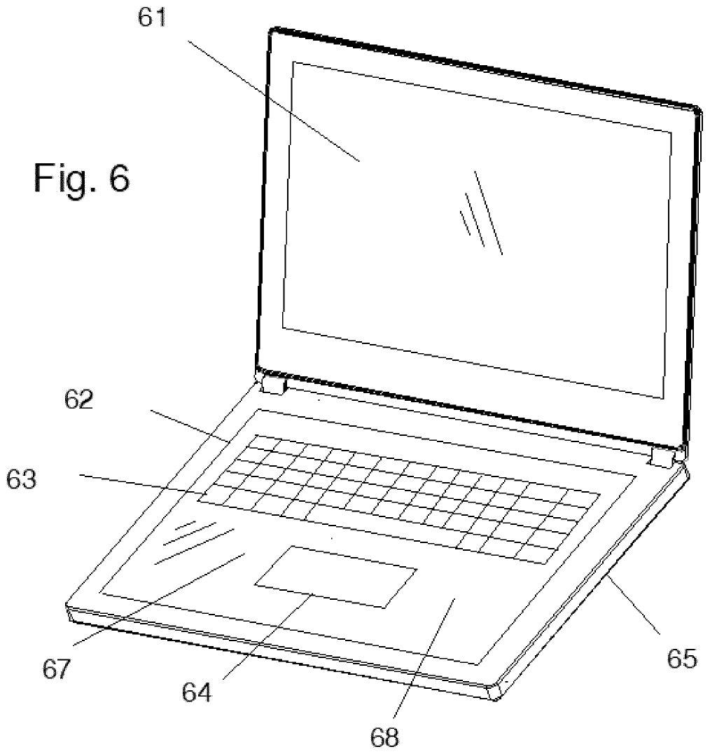

FIG. 5 illustrates the embodiment of FIG. 4, having an image of a virtual keyboard 54 displayed on the second screen 52 to allow the user to input text and commands into the laptop as needed. For some users it is important to have a real physical keyboard as previously shown in FIG. 3, but for many users it will be quite acceptable and convenient in the future to use a virtual keyboard in a laptop, especially for those users who have become accustomed to using a virtual keyboard display in smart phones and tablet computers. Of course that requires that the second screen 52 be equipped with an appropriated touch panel on top of the second display 52 to make it touch-sensitive. Since the second display 52 is touch-sensitive, there is no need for a separate touchpad such as touchpad 13 on FIG. 1. The second screen 52 can serve as a touchpad or display a touchpad as needed, as shown in FIG. 6.

FIG. 6 shows a laptop with two full-size displays 61 and 62, and no physical keyboard. Instead of a physical keyboard, a virtual touch sensitive keyboard 63 is implemented using touch-sensitive second display 62. A virtual touchpad 64 is also implemented using touch-sensitive second display 62. The areas on both sides of the touchpad 67 and 68 can serve as convenient hand-rest areas for users typing on the virtual keyboard. These areas can be temporarily touch-disabled by the laptop's software to allow the user to rest his/her hands on those areas without triggering false touches. Alternatively, the touch sensitivity can be disabled for the whole second screen 62 except for the keyboard and/or touchpad areas while in touchscreen and/or touchpad mode to prevent any false touches anywhere except within the touchscreen and/or touchpad areas.

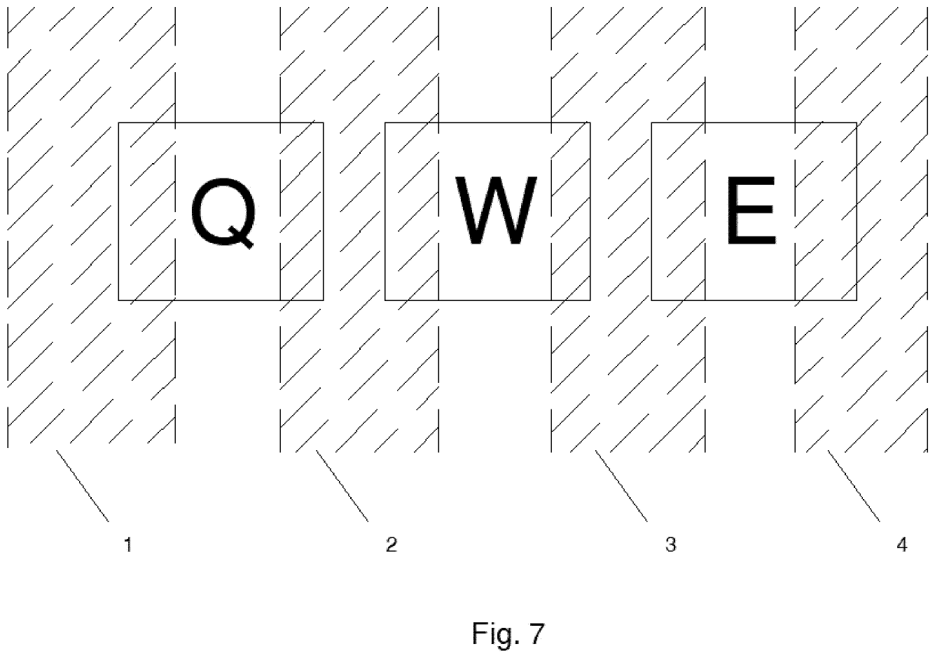

Another important feature of certain embodiments is the ability to increase the precision of the virtual keypad and prevent false touches and misspelling by touching the neighboring key(s) in the keyboard, as commonly occurs using smartphones. To avoid that problem, each key of the virtual keyboard can be programmed to have a central touch-sensitive area, with areas surrounding the central touch-sensitive area made touch-insensitive by the laptop's software, firmware and/or hardware. Therefore, the probability of accidentally touching a neighboring key and therefore causing a misspelling is substantially reduced, because the touch-sensitive area of the neighboring key is relatively distant. This is greatly facilitated in a laptop (as opposed to a smartphone) by the much larger area available for the keyboard, which increases the feasibility and effectiveness of surrounding each key by touch-insensitive lanes, as shown in FIG. 7.

FIG. 7 shows each that each key of the virtual keyboard (such as the display areas corresponding to characters Q, W, and E as shown) can be surrounded by touch-insensitive lanes such as 1, 2, 3 and 4, which insulate each key with respect to its neighbors, greatly reducing the probability of false touches, such as for instance inadvertently triggering W instead of Q if the finger trying to touch the display area corresponding to key Q is a little offset to the right and therefore accidentally touches a portion of the display area corresponding to the key W. FIG. 7 shows only vertical touch-insensitivity lanes for clarity of the drawing and the description, but similar lanes can be additionally created in horizontal direction, insulating each key from its neighbors above and below.

The scenario previously shown on FIG. 6 can be used as the first set of screens the user sees when it boots this laptop (start-up screen), for easy transition for users from older generation laptops with only one screen to the new generation of multi-screen laptops. The advantage of this setup is that the virtual keyboard 62 and the virtual touchpad 64 can be erased by the software when not needed, and the two full screens become available for vastly expanded total display area and multi-tasking capabilities.

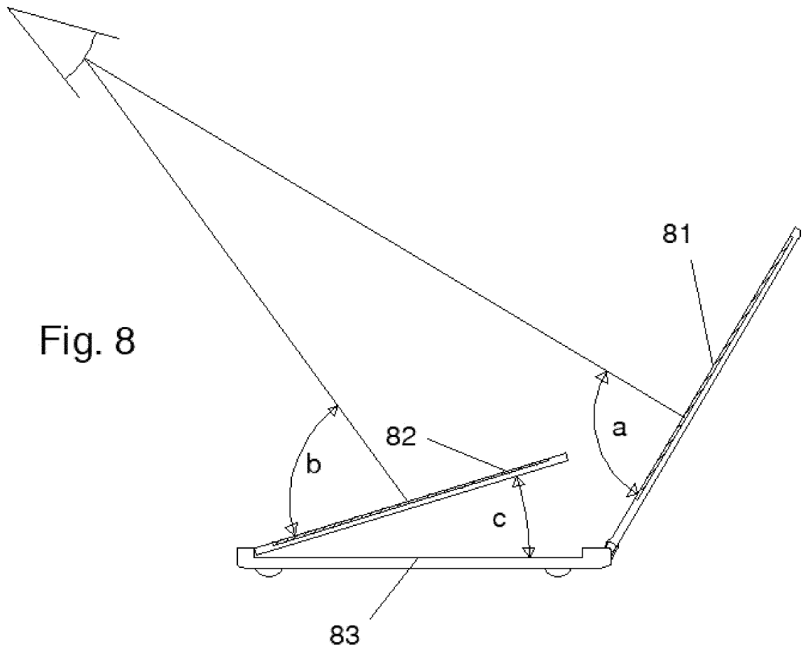

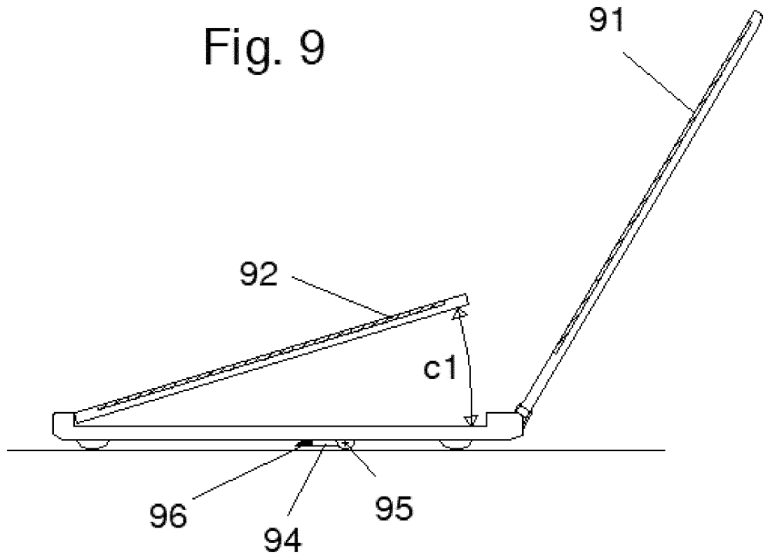

FIG. 8 shows that by rotating the second display 82 up by an angle c, the user can achieve a more favorable viewing angle b (such as an angle closer to perpendicular), which leads to a higher quality, sharper image of display 82 as perceived by the user. At the same time, the user is free to rotate the primary display 81 about its hinges, adjusting viewing angle a to the best perceived image quality for display 81. Optimization of view angles is an important advantage of the dual adjustable screens shown in this embodiment. However, if the user increases the angle c too much, at some point the display 82 may partially obstruct the user's view of display 81. This limitation can be overcome with the embodiment of FIG. 9.

FIG. 9 shows the laptop equipped with main display 91, second display 92 and a deployable incline mechanism 94, which is rotatably attached to the base of the laptop about axis 95, and with a support tip 96, which can be made of a non-slide material such as rubber. In FIG. 9 the incline mechanism is shown in non-deployed position. Second display 102 is inclined by angle c1.

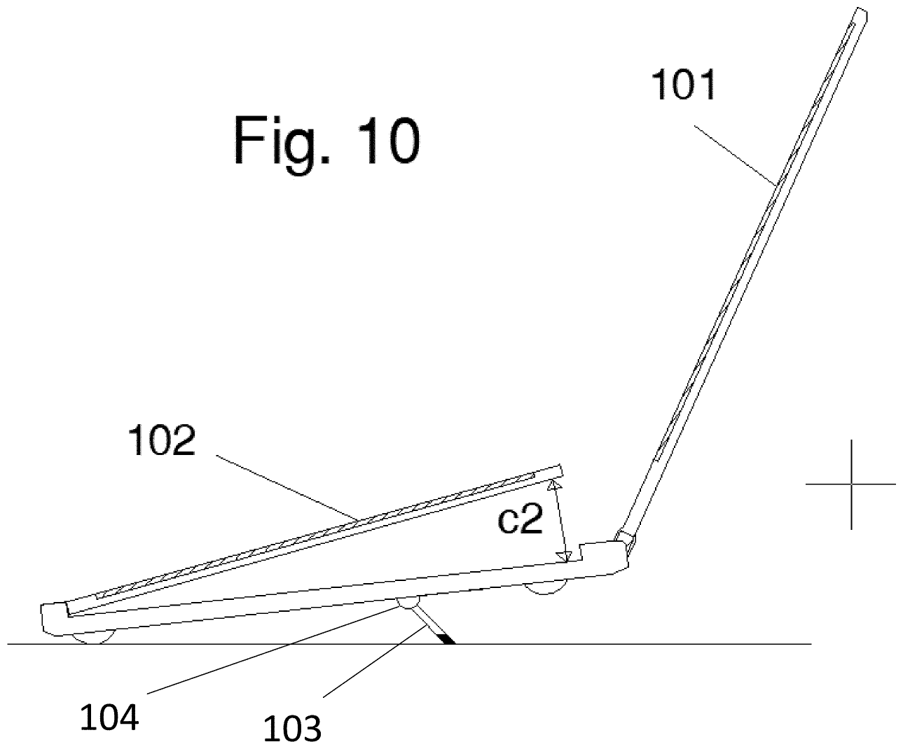

FIG. 10 shows an incline mechanism such as that of FIG. 9, in deployed position. The incline mechanism can be deployed by the user by rotating the support 103 counterclockwise about a pivoting structure 104 until it reaches a stop. The effect of the deployment of the support 103 is an upward incline of the laptop base. As a result of the incline angle, the user needs a smaller angle c2 (wherein c2<c1 from FIG. 9) to achieve the user's desired viewing angle, eliminating or minimizing the potential view blockage issue between second display 102 and primary display 101. The support structure can be freely rotatable with one single stop (as shown in FIG. 10), but alternatively it can be designed to be discretely adjustable (multiple stops) or continuously adjustable (friction mechanism or similar), to provide different possible laptop incline positions.

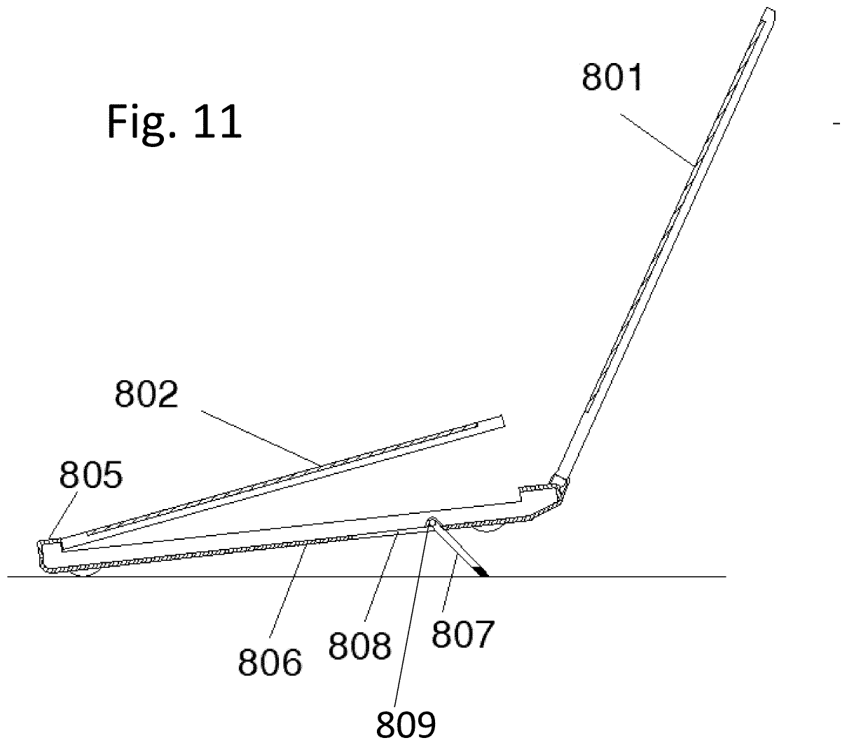

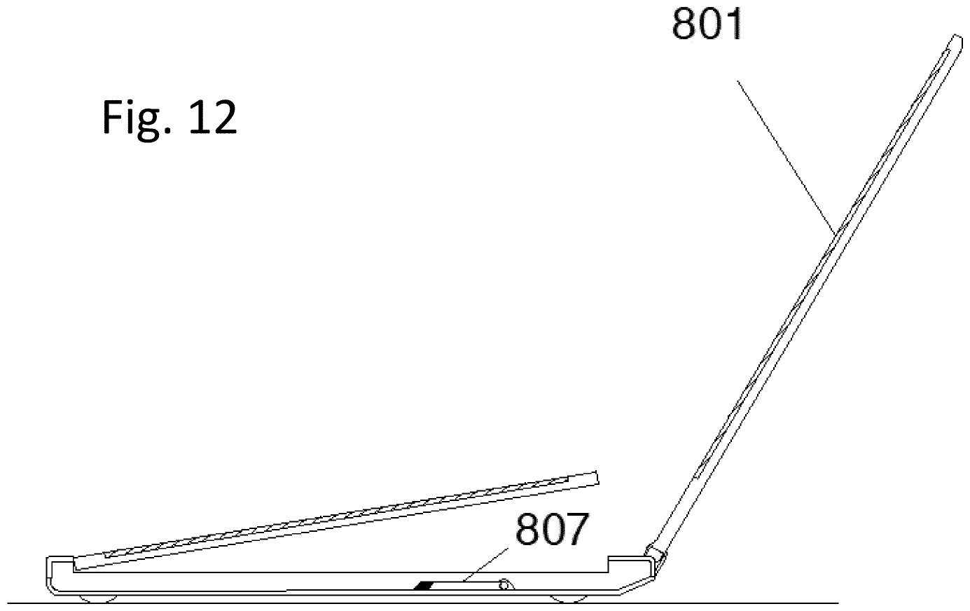

FIG. 11 is another embodiment of the incline mechanism wherein the pivot structure is substantially inside the laptop housing (as opposed to under the laptop housing, as shown in FIG. 10). The embodiment of FIG. 11 has the major advantage that the pivoting structure is contained inside the laptop housing, between the bottom panel 806 (also called the D-panel in industry terminology) and the top panel 805 (also called the C-panel), thereby avoiding an increase in laptop thickness. One of the most important requirements in laptop design is to minimize laptop thickness, and this type of incline mechanism helps significantly in that regard. FIG. 12 shows that when the incline mechanism 807 of FIG. 11 is stowed away (undeployed), the mechanism is either inside the laptop housing or at least flush with the bottom of the laptop, without increasing laptop thickness.

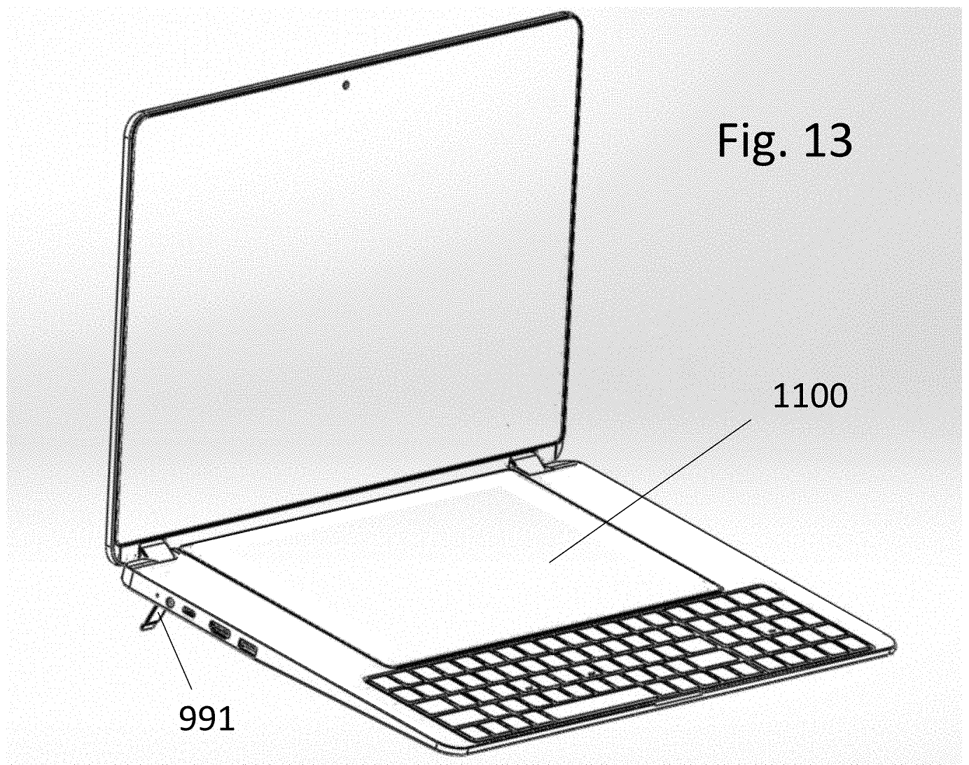

FIG. 13 shows application of incline mechanism embodiments described herein to any type of multiscreen laptop, including a dual screen laptop wherein the secondary screen 1100 is fixedly mounted in the laptop housing (not adjustable). In FIG. 13, the screen 1100 does not offer any adjustment to the user relative to the base unit in which it is set, and the image quality in many conditions would be inadequate because of the wrong viewing angle with respect to the user or because of overhead lights being reflected on the screen. The incline mechanism 991 can substantially improve the user experience by allowing the user to adjust the angle of the laptop (and therefore the angle of screen 1100) and then adjust the angle of the main screen accordingly.

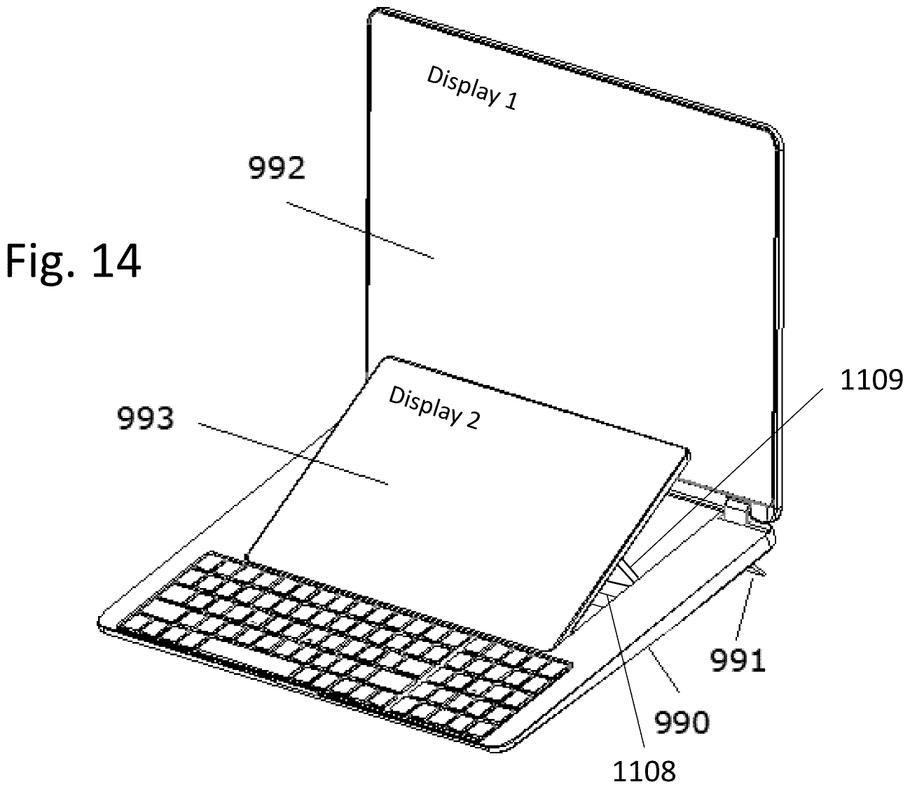

FIG. 14 shows that the incline mechanism previously described can be used with a dual screen laptop where the secondary screen can be either full size (no physical keyboard on the laptop, as shown in FIG. 12) or partial size (such as screen 993, which is partial size only to make space on a top surface of base unit 990 for a physical keyboard). The laptop is further equipped with an optional support mechanism 1109 that holds the screen 993 steady at any angle desired by the user. The support bracket 1109 can be hinged about the back of the screen 993. Notches 1108 can be provided in the laptop bay to facilitate stopping and keeping the support bracket 1109 in desired discrete positions. Alternatively, a rotational friction mechanism connecting the support structure 1109 to the back of screen 993 can be used to provide continuous angle adjustability for the support bracket 1109. This support structure 1109 can be a great convenience for the user, and it is also advantageous when working with a stylus on screen 993, by keeping the screen 993 in a steady position. In FIG. 14, the incline mechanism 991 is shown in deployed position. The integrated incline mechanism with a pivoting structure substantially inside the laptop housing is particularly useful for this type of multiscreen laptop, because the hidden pivoting structure for the secondary screen 993 can make it challenging to keep the laptop thin. Therefore an incline mechanism that doesn't increase thickness further is a definite advantage.

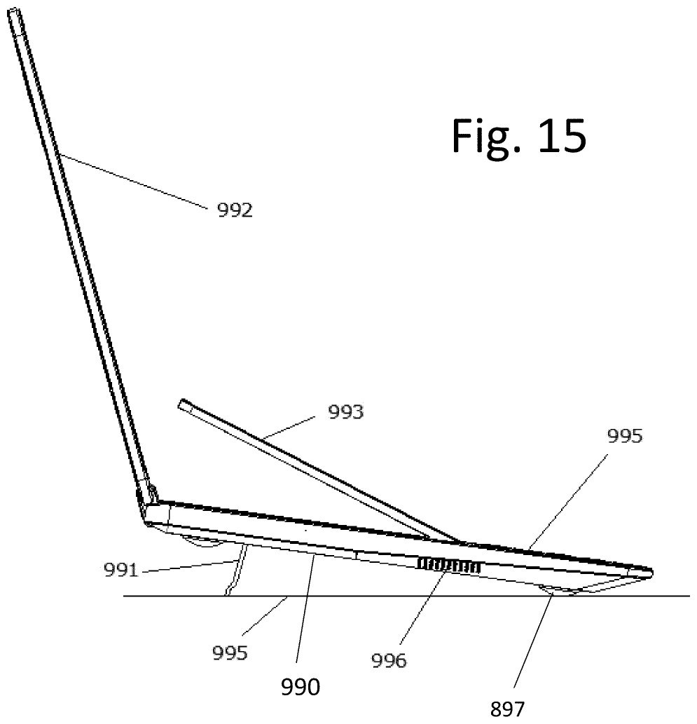

FIG. 15 shows a side view of a multiscreen laptop with deployed incline mechanism, sitting on a desk surface 995. In the front (furthest from a user during normal use), the laptop is supported by the support 991. In the rear (closest to the user during normal use) the laptop rests on its rubber feel 897 which are shaped like rounded buttons to facilitate consistent contact with surface 995 while base 990 is placed into varying states of incline. The incline mechanism and the feet are mounted on the D-panel, which is the bottom shell of the laptop.

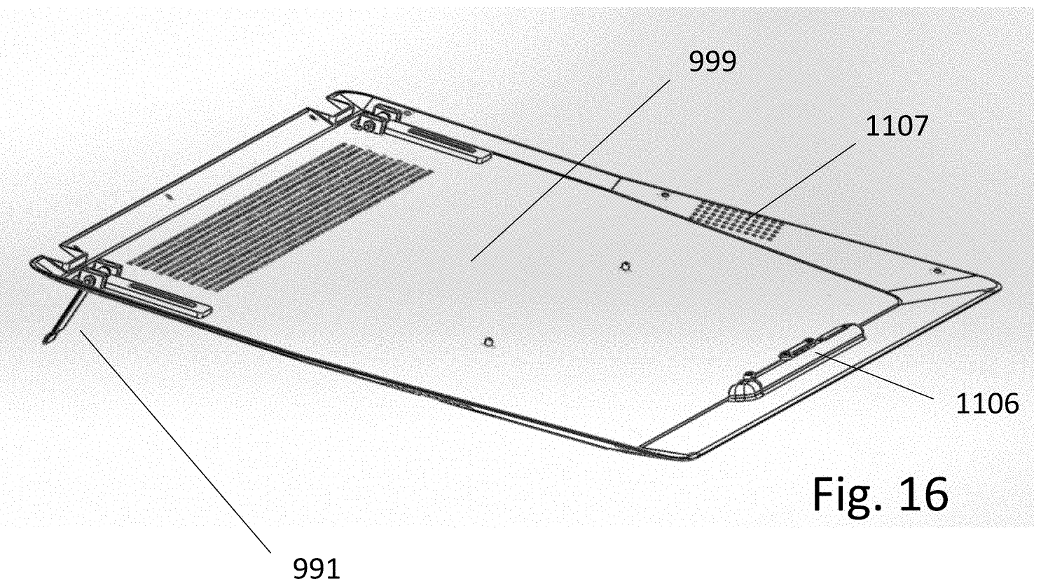

FIG. 16 shows the D-panel in more detail. The basic shape of the D-panel includes a substantially flat portion in the center, with significantly slanted areas around it. The rear slanted area is used to house a stylus in a stylus compartment 1106 that allows the user to write on the screen, particularly in the secondary screen, which is optimally suited for that purpose because of its substantially flat and steady position and proximity to the user during normal use. Use of a stylus on a secondary, base unit display screen is much preferred over prior attempts that have been made to enable the user to write on the main screen, which is too far away from the user, forces the user to hold the pen in the air and creates screen hesitation and oscillation every time the user touches it. By contrast, the secondary screen offers convenient hand support for the user and the screen is steady because it sits on the desk. The stylus housing 1106 includes a small PCB that keeps the stylus charged at all times in this handy compartment.

Another feature of the D-panel in FIG. 16 is the set of orifices 1107 on the lateral slanted areas. The advantage of that location is that the laptop does not need any unsightly orifices on its side walls, which are too small anyways for unimpeded sound. The slanted side location creates a divergent resonance sound chamber between the slanted lateral surface of the D-panel and the desk surface, which substantially improves sound quality.

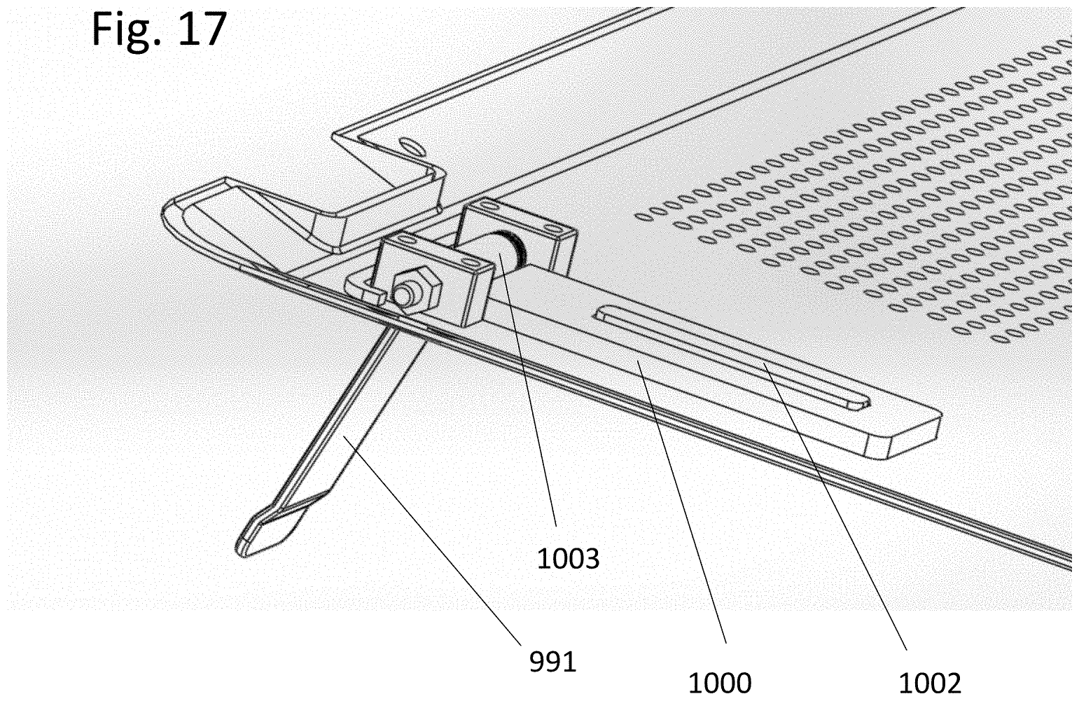

The other key feature of the D-panel in FIG. 16 is the already described incline mechanism 991. This is shown in more detail in FIG. 17.

FIG. 17 shows the incline mechanism, which basically consists of a rotatable support beam 991 which pivots around a shaft 1003, which is rotatably attached to pillow blocks attached to the D-panel. Sufficient friction can be provided in this hinge mechanism to provide a better feel for the user, by avoiding free-dangling of the support beam when removed from its storage compartment 1000. Also, if enough friction is provided to support the weight of the laptop and pressure applied (e.g. by a user's hands) during typical laptop use with moving rotatable support beam 991, this mechanism can be set by the user to almost any desired angle, not just to the maximum angle provided by the stop at the end of its stroke, making it continuously adjustable. The D-panel has a compartment 1000 that completely contains the support beam when it is un-deployed, ie. folded back into the D-panel with a counter-clock rotation in FIG. 17. In embodiments in which rotatable support beam 991 is formed from a material attracted to magnets (e.g. a ferromagnetic metal), a magnet 1002 may be positioned on a top portion of compartment 1000 to help keep the rotatable support beam 991 retained inside the compartment 1000 when rotatable support beam 991 is in a stowed away or undeployed position.

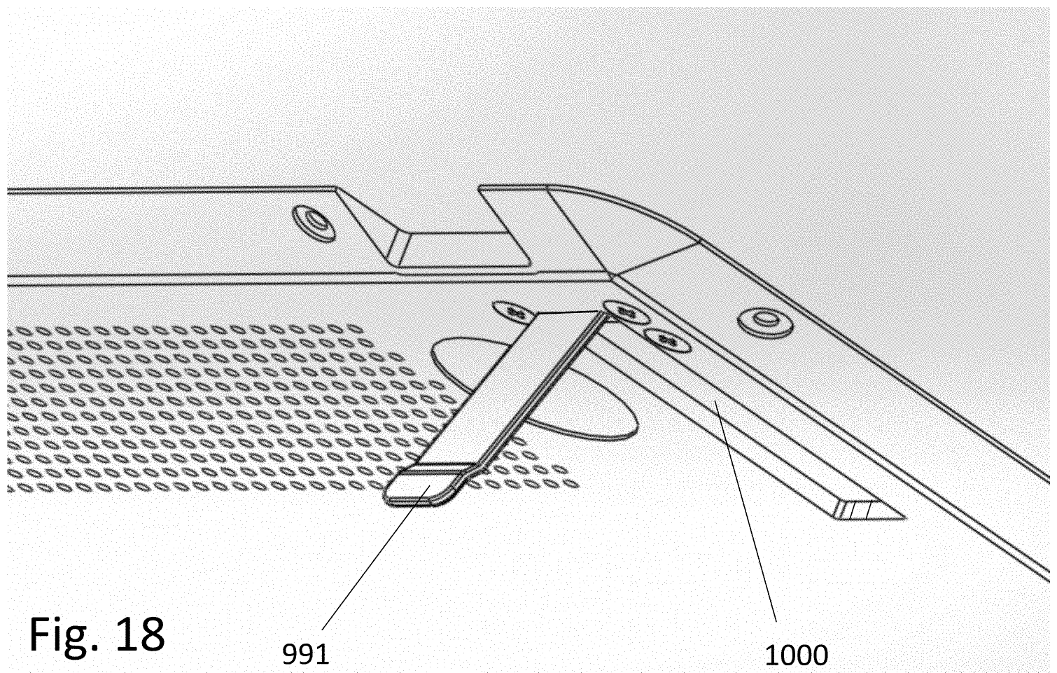

FIG. 18 is a partial bottom perspective view of the incline mechanism of FIG. 17. The support beam 991 is in deployed position. To un-deploy or stow it, the support beam 991 is turned in counter-clock direction and stowed away inside the cavity 1000, so that the support beam is flush with the bottom surface of the D-panel. The tip of the support beam has a bend at its end such that it extends downward from the bottom surface of the D-panel when stowed, providing a mechanism for a user to easily deploy it by extracting it from cavity 1000.

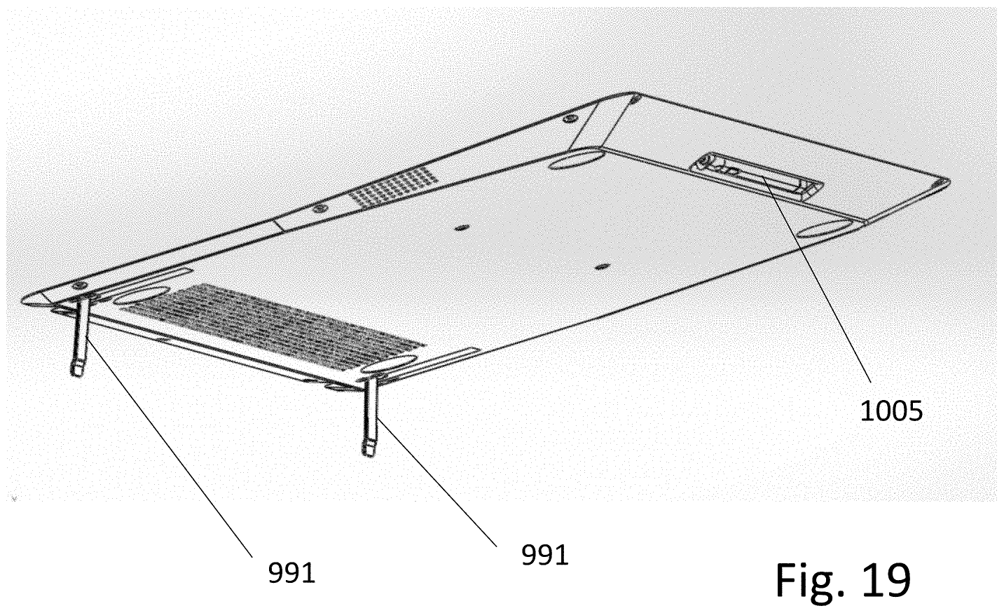

FIG. 19 is a full bottom perspective view of the D-panel showing the two support beams 991 of the incline mechanism near the front left and right corners (i.e. furthest from the user during normal use), and the stylus compartment 1005 near the rear of the D-panel.

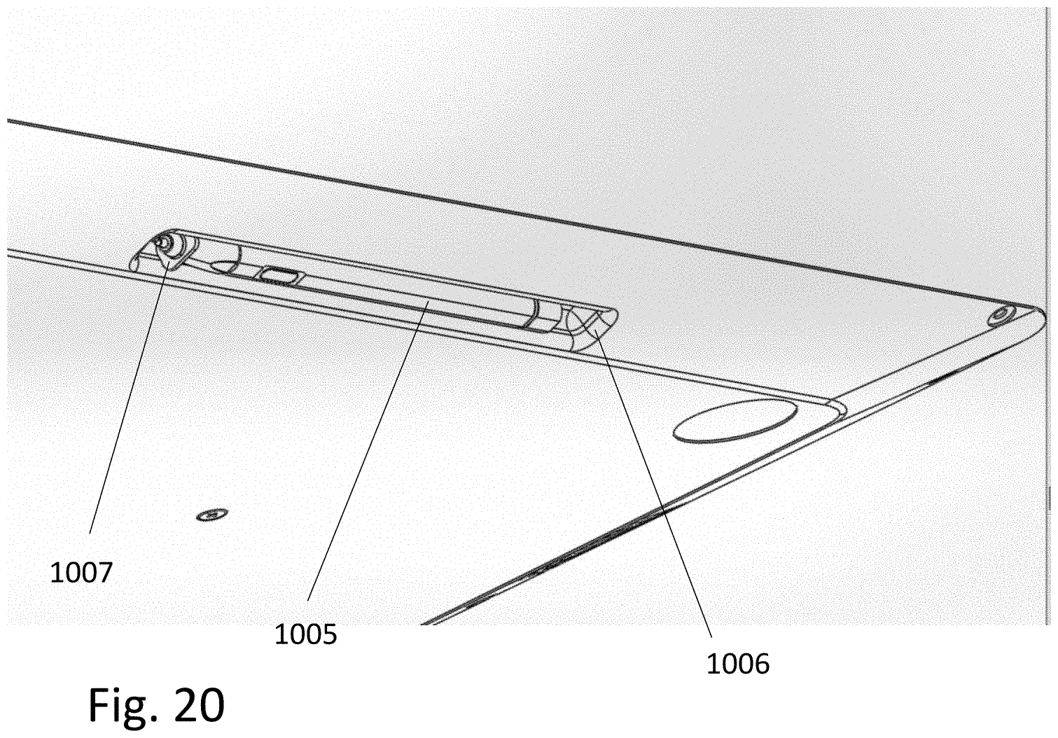

FIG. 20 is an expanded bottom perspective view showing more details of the stylus cavity 1006. The stylus 1005 is held by a hook 1007 in the front, and a magnet near the rear of the stylus. An alternative embodiment could replace the magnet with a spring loaded mechanism to hold the stylus in place. Another embodiment can eliminate the hook at the front and just use two magnets. Further variations exist of course.

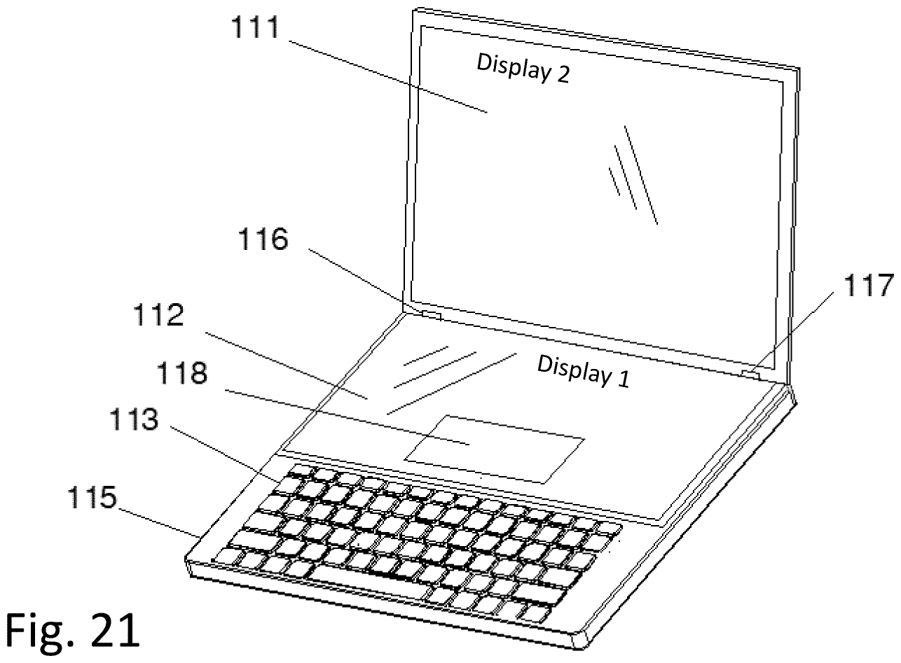

FIG. 21 shows another embodiment wherein a first display 112 is rotatably attached to the base 115 through hinges or similar mechanism located near the top edge of the keyboard (these hinges are not shown in FIG. 21, because typically these hinges will be hidden inside the laptop base). The second display 111 is rotatably attached to the first display through hinges 116 and 117. This embodiment of the invention also includes a physical keyboard 113, which reduces the space availability for display 112. Therefore display 112 has to be made smaller than display 111, but for many users that is a very acceptable compromise if they need a physical keyboard for high speed and high precision typing. In FIG. 21, the first display 112 is shown in non-deployed position (folded down and stowed into the laptop base 115).

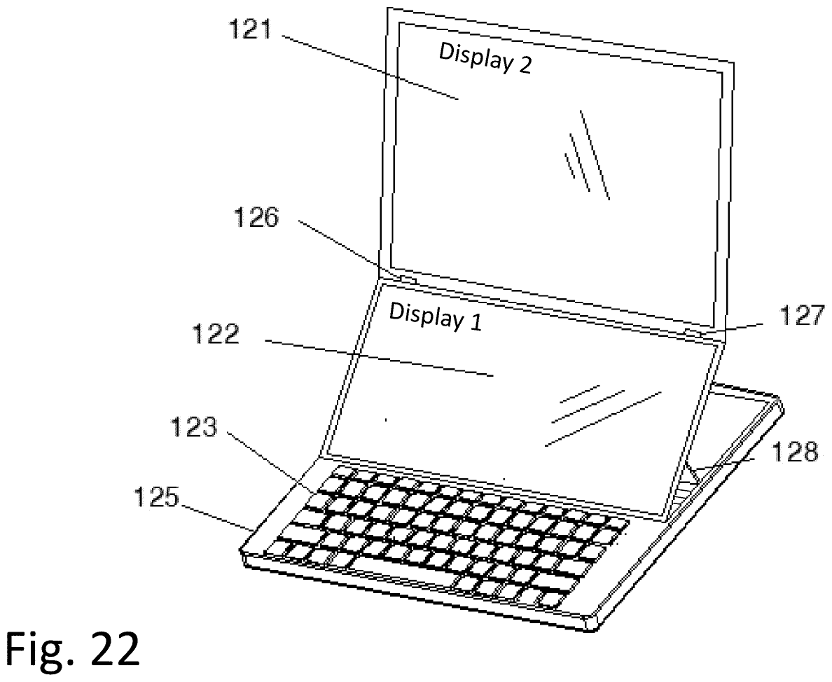

FIG. 22 shows the embodiment of FIG. 21 with a first display 122 now in a raised, deployed position. The hinges of first display 122 are not visible because in this embodiment the hinges are hidden inside laptop base 125. External visible hinges can be provided too. Elevation of first display 122 in turn elevates second display 121. Hinges 126 and 127 interconnect first display 122 with second display 121, allowing second display 121 to be adjusted to maintain a desired angle relative to a user's view. Because second display 121 is attached to and moves with first display 122, the configuration of FIG. 22 inherently avoids circumstances described hereinabove in which one display may obstruct view of another.

To close the laptop embodiment shown in FIGS. 21 and 22, display 121 folds down onto display 122 via articulation of hinges 126 and 127, such that the display screens face one another (i.e. in a clamshell configuration relative to one another). Then, display 122 folds down and stows into an upward-facing receptacle in laptop base 125 via articulation of hinges at a lower edge of display 122, attaching display 122 to base 125. An optional support structure 128 may be provided to support display 122 (and indirectly, display 121), preferably preventing oscillation of the displays 121 and 122 when the user touches, e.g., display 122. Support structure 128 may include a plate or a set of plates, or a set of poles, that stabilize the display 122. The support structure 128 can be rotatably attached to the back of the display 122, or to the laptop base 125 itself (e.g. to a receptacle beneath display 122 into which display 122 recesses when stowed), or both. In some embodiments, support structure 128 can be manually deployed by the user as needed; in other embodiments, support structures may be automatically deployed (e.g. spring-biased or electrically-actuated). A possible alternative to the support structure 128 is a lock mechanism based on a hinge between the laptop base and the display 122. The hinge allows free rotation of the display 122 until a stop in the hinge is reached, which engages and holds the display in that position until manually released by the user to close the display 122. The hinge can be a friction-based hinge or a non-friction hinge. The incline angle of the display 122 can be fixed by design or user-chosen.

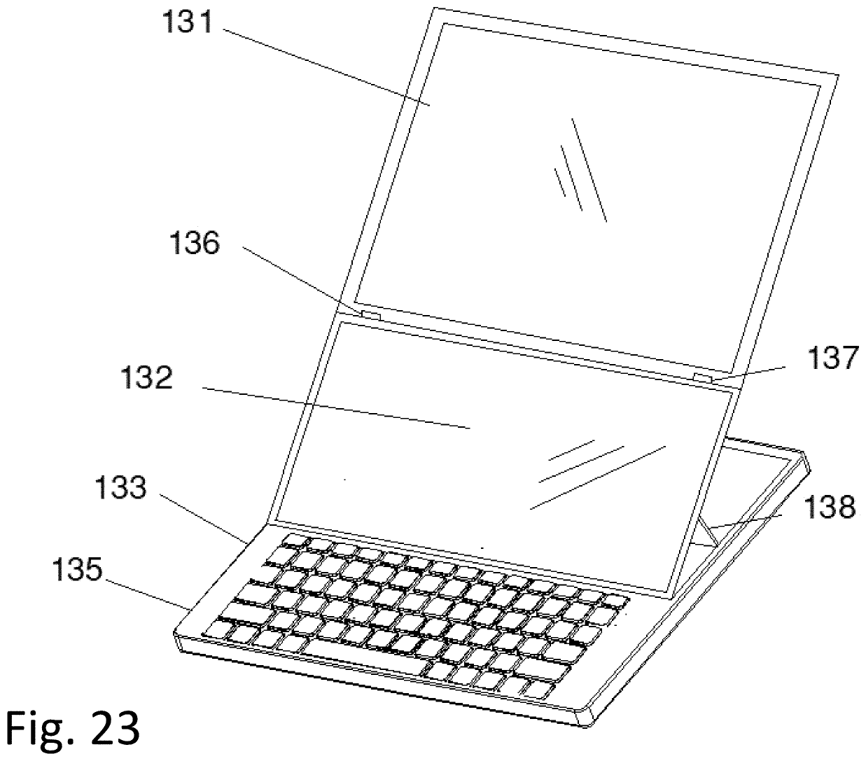

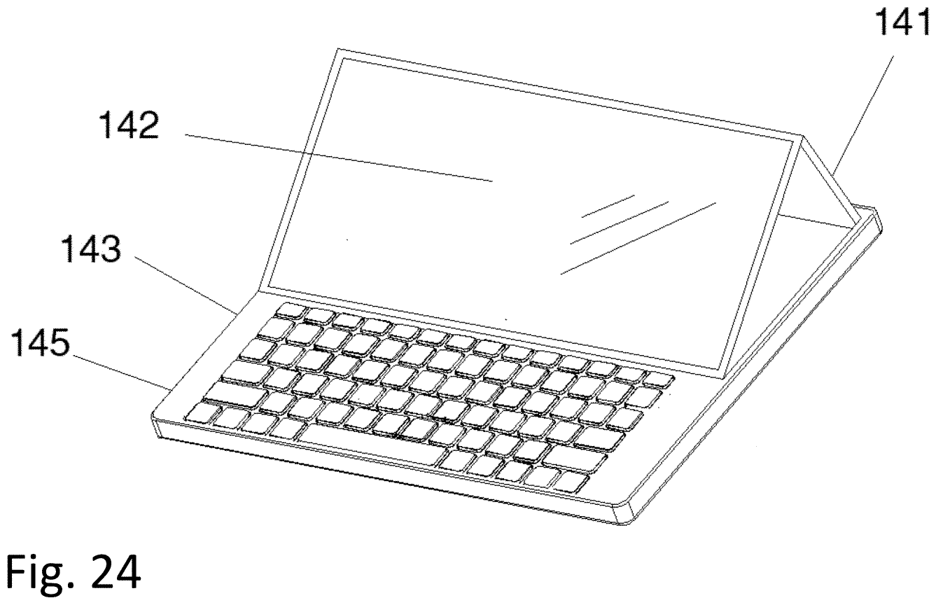

One of the advantages of the embodiment of FIG. 22 is that the two displays can be aligned substantially parallel to each other, as shown in FIG. 23, so that the two displays can together constitute one very large display, which is desirable for certain applications. Another advantage of this embodiment is illustrated in FIG. 24, which is that the upper display 141 can be folded down to face another person sitting opposite the laptop user, while a lower display 142 faces the user with access to a keyboard within laptop base 145. Such a configuration provides a mode of operation useful for presentations to other individuals within a room.

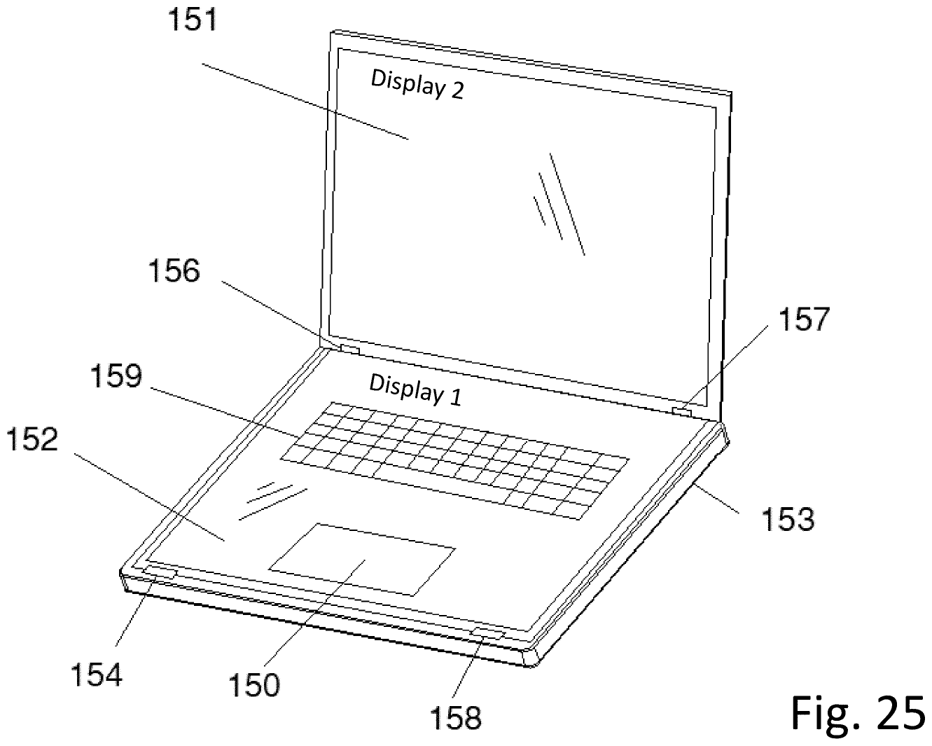

FIG. 25 shows another embodiment, wherein both the first display 151 and the second display 152 are large, full-size displays, i.e., first display 151 occupies the majority of the surface area of the display unit side in which it is set, and second display 152 occupies the majority of surface area of the upward-facing (during use) surface of base unit 153. The display 152 is hinged to laptop base 153 via hinges 154 and 158, rotatably interconnecting display 152 and base 153 proximate edges of each closest to the user during use. The first display 151 is rotatably attached to first display 152 via hinges 156 and 157, proximate a portion of display 152 furthest from the user during normal use and a portion of display 151 closest to the user during normal use. This laptop can display a virtual keyboard 159 and a virtual touchpad 150 using second display 152, which can be removed by the software when not needed by the user. In FIG. 25, second display 152 is illustrated in a horizontal, non-deployed position, stowed into laptop base 153.

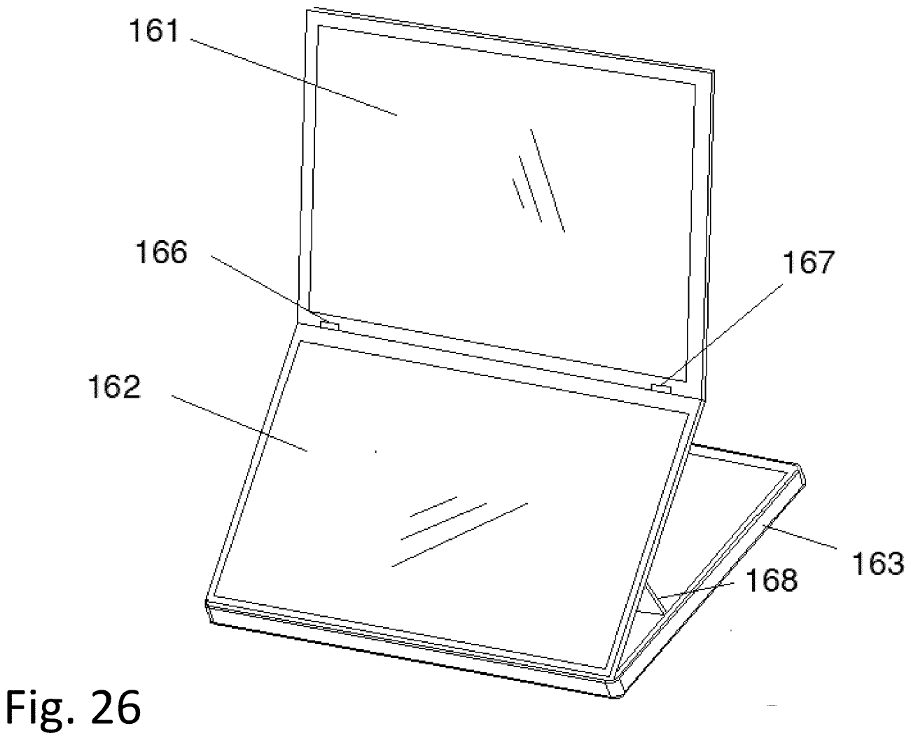

FIG. 26 shows the same embodiment of FIG. 25 with the second display 162 now in deployed, elevated position. First display 161 in turn is elevated relative to base 163 by virtue of its attachment to the upper edge of second display 162. The viewing angles of both second display 162 and first display 161 are adjustable for optimal image quality. The optional support structure 168 can be used to stabilize the display 162, in a similar manner as described above in connection with support structure 128.

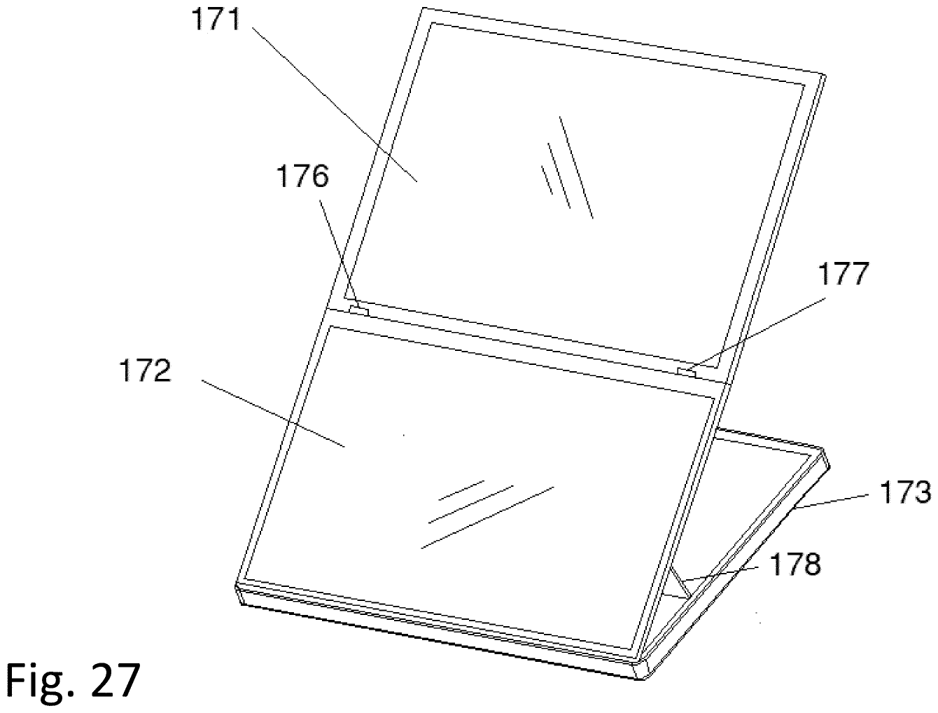

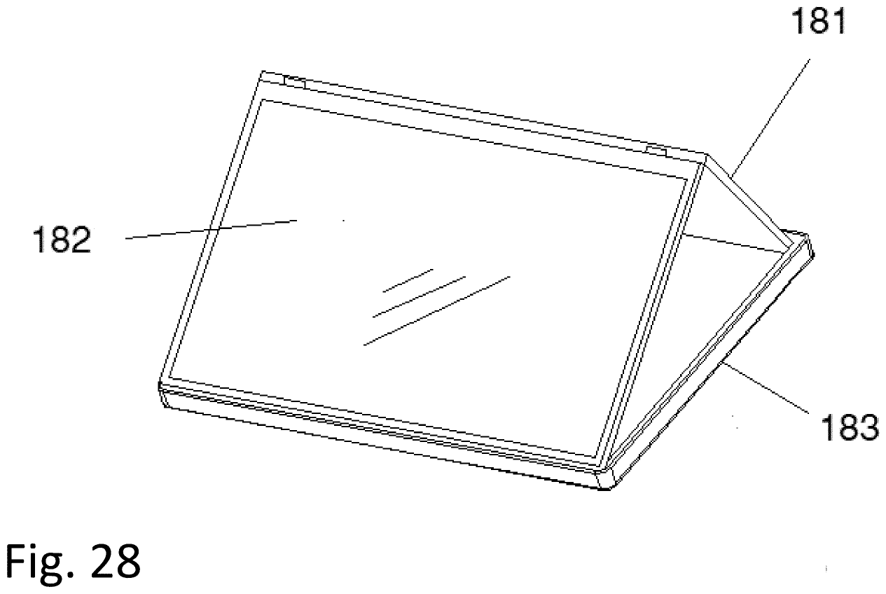

FIG. 27 shows that the embodiment of FIGS. 25 and 26, with the first and second displays configured in a different orientation. In particular, first display 171 and second display 172 can be aligned parallel to one another, preferably coplanar. In this alignment, the displays may utilized by the user as an equivalent of one very large display, which is ideal for certain applications. FIG. 28 shows that another advantage of the embodiment of FIGS. 25-27. The hinges connecting first display 181 with second display 182 may be articulated greater than 180 degrees, such that first display 181 can be folded down to face another person sitting opposite the laptop user, while the laptop user utilized second display 182, thereby providing a presentation mode.

Turning now to the software side, embodiments described herein include new powerful software methodologies and features that can dramatically enhance the user experience and user productivity for users of any multi-screen laptop computer, including but not limited to those multi-screen laptop computers based on the prior art hardware architecture of the '097 Patent, or based on the above-described hardware architectures, or on any other multi-screen laptop architecture. Some advantages and benefits of any multi-display laptop architecture are actualized only with the new innovative software methodologies and features described herein.

The innovative software methodologies and features described herein can be implemented at the application level, or at the operating system level/BIOS level or both. Therefore they can reside in the application software, and/or in the computer firmware that contains the Operating System and the BIOS, or both. These innovative software methodologies and features for multi-screen laptop computers are described below.

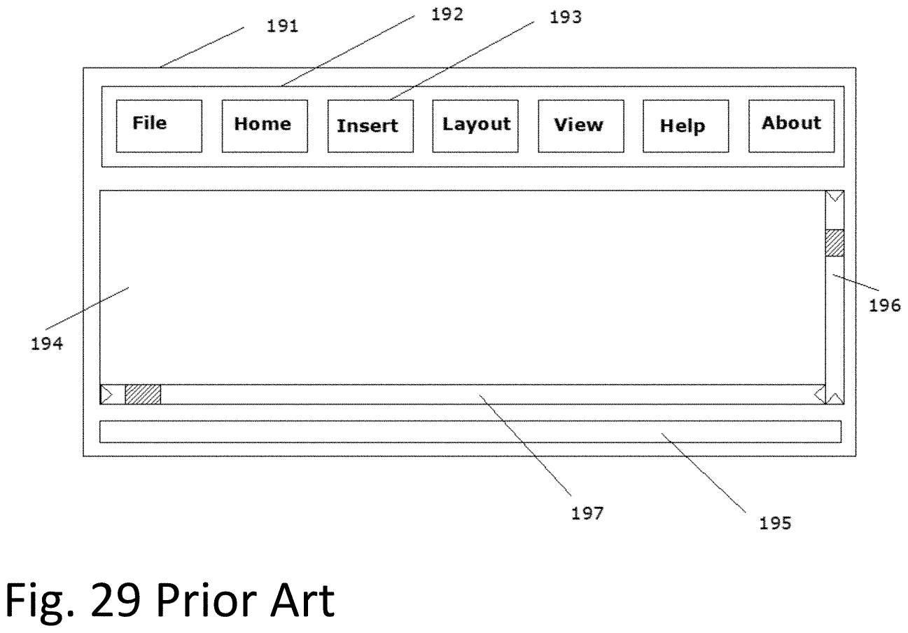

FIG. 29 illustrates an example of traditional prior art software methodology which is based on a single laptop display because that was the only possibility in single-screen laptops. The display area 191 includes the workspace 194, which is the area where the object being created or modified by a software application is shown to the user, so that he/she can work on it. For example, the workspace in a word processing application is the area where the document being created or modified is shown in a word processing application; or where the photo or image being edited is shown in a graphics application such as Photoshop; or where the drawing of a structure being created such as a building or bridge is shown in a 2D architectural CAD application; or where a 3D image of a mechanical part such as a gear or a shaft is shown in a 3D CAD application; or where the presentation slides are displayed in a presentation app such as Powerpoint, etc. The workspace 194 is the most important area, but in traditional prior art single-screen applications the workspace is only a shrinking fraction of the total available display area, because the software application also needs substantial space for ancillary functions such as menus, dialog areas, support areas, navigations bars, option bars, help functions and other ancillary functions that significantly reduce the space available for the actual workspace 194. Around the workspace 194 there are several other areas for ancillary functions, such as (in this example): the menu area 192, which contains tabs (such as File, Home, Insert, etc.); the vertical scrolling bar 196, to move application objects up or down; the horizontal moving bar 197 to move application objects horizontally; a status and/or dialog bar 197, used to display some app stats or information or user communication; and other ancillary areas not shown in FIG. 29.

This approach, while necessary in computers with only one display, has the disadvantage that it limits the available space for the workspace. The workspace shrinks, and the user has to make do with a reduced space which makes it difficult to look at the whole object being created, forcing the user to zoom onto parts of it only, which can result in loss of context, reduced productivity, increased probability of errors and suboptimal final results.

With increasing complexity and sophistication of the software applications this problem keeps getting worse, because more and more space is needed for user guidance and support, which causes additional shrinkage of the workspace and compromises with insufficient guidance/support areas and/or insufficient space available for the vital workspace 194.

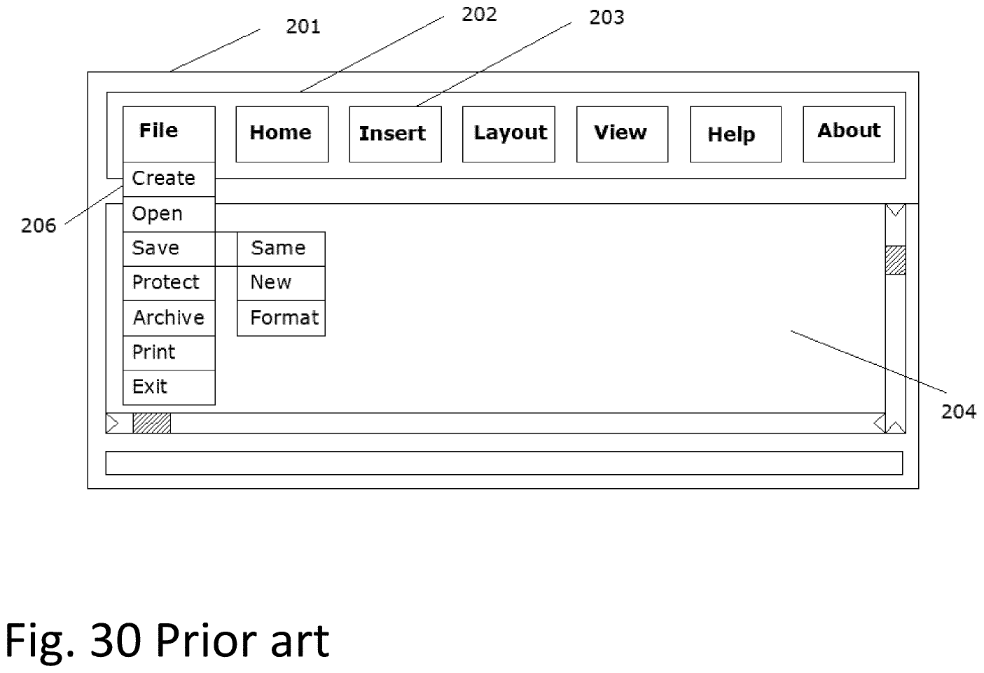

FIG. 30 shows that not only is the workspace 204 unduly reduced in size by the ancillary areas, but it is also often encroached upon by the software for its operation. The typical drop-down menu 206 expands vertically and often also horizontally, invading the workspace 204 and obstructing the view of the object being worked on, causing obfuscation, loss of context, confusion and loss of productivity and quality of the object created by the app, such as for example the quality of a design being created inside the workspace 204, which the creator has trouble seeing in its entirety because of the limited size and encroachment.

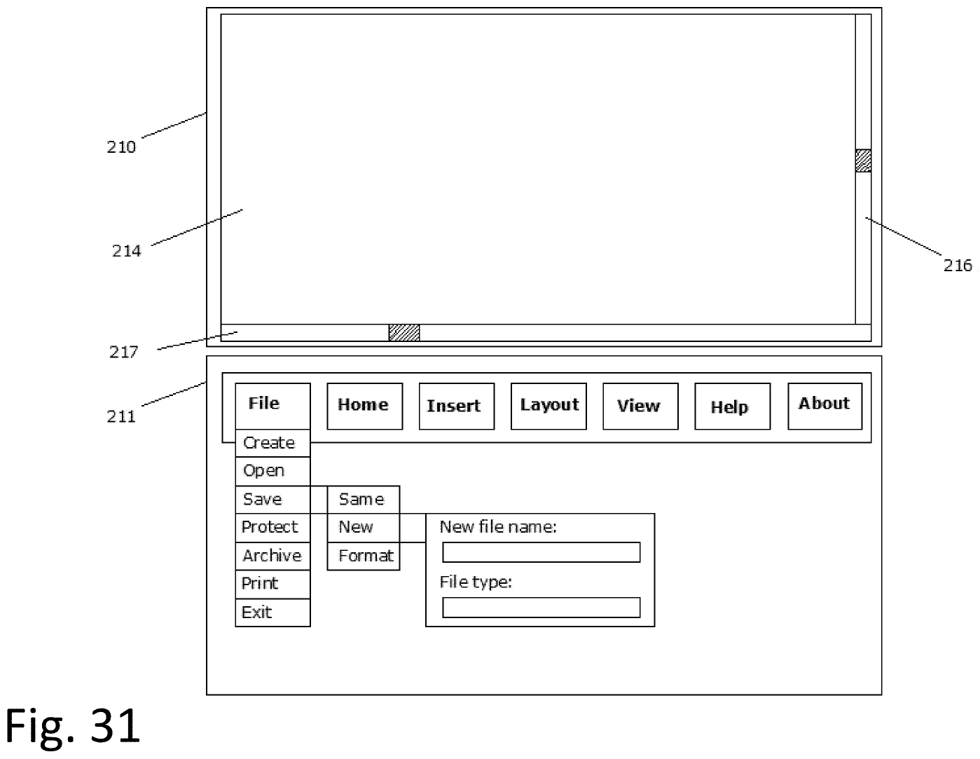

FIG. 31 shows a first embodiment of the new software methodology of the present invention relying on 2 displays, display 210 and display 211. Display 210 is used primarily as workspace 214, and possibly including navigation bars such as 216 and 217, while the other display 211 is used primarily for ancillary functions such as menus, submenus, commands and interaction with the user. This novel software design approach makes it possible for the workspace 214 to remain clean, unobstructed and non-obfuscated, creating a better user experience, higher productivity and a higher quality result in the objects so created. The large workspace 214 can provide a wealth of information, context and detail that a small workspace is just not physically able to provide, and the user can see objects with better context and with a much higher level of detail and with a reduced need to zoom into partial views to see details.

Description of a user interface workspace as large or small refers in particular to the proportion of display screen space allocated to the workspace. It is contemplated and understood that embodiments of the present invention may be implemented on display screens of varying sizes. However, by providing a display screen that is entirely or primarily dedicated to an application workspace, the user may benefit from maximizing software usability within a given physical display form factor.

The transfer of menus and command systems to the second screen need not be absolute and complete. Some command functionality can easily be retained in the workspace, for instance by using the left button in the mouse, by entering a certain code on the keyboard or even by a gesture on a touch-sensitive screen. That makes the software easier to use, saves time and increases productivity, by enabling the user to perform some frequent or repetitive tasks without leaving the workspace, but without obstructing or obfuscating the workspace.

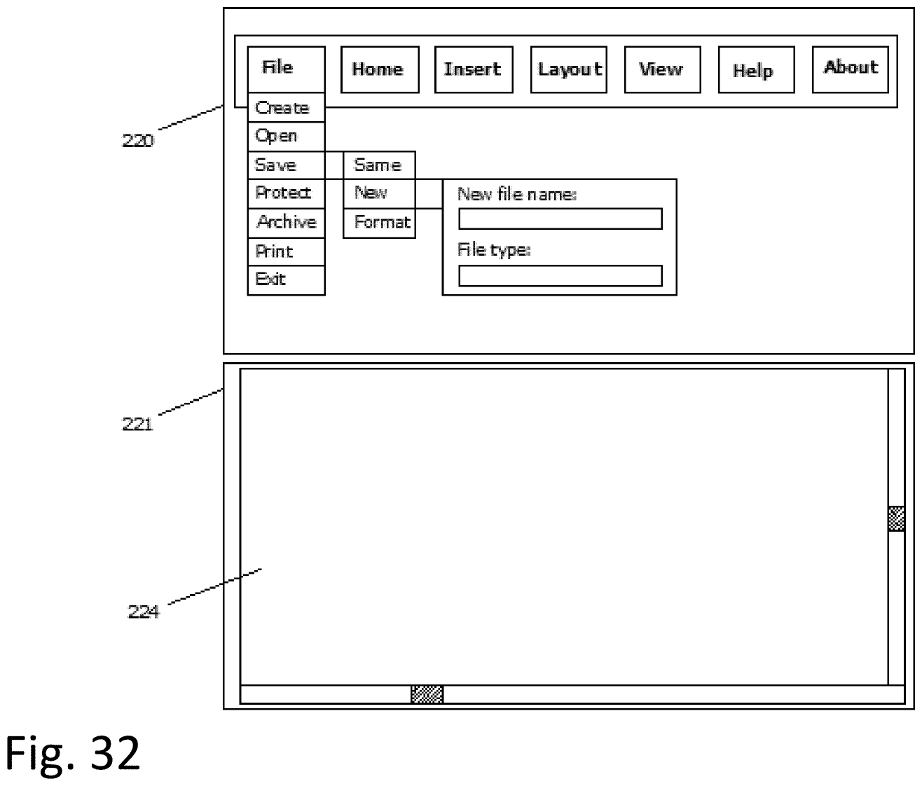

FIG. 32 shows that the roles of the two displays 220 and 221 can be reversed or reassigned by the user at any time, for instance assigning the workspace 224 to the lower display and the command, support and ancillary functions to the upper display. This can be especially advantageous if the lower screen is equipped with a touch panel making it touch-sensitive. The upper screen is not ideal as a touchscreen because it is tiring and inconvenient for the user to lift and extend his/her arm to touch the upper display, while the lower display may be more easily touched by the user (e.g. using one or more fingers or a stylus). Another disadvantage of a touchscreen in the upper display is the fact that when the upper display is touched, the whole display tends to hesitate and oscillate about its hinges, which is an annoying effect that hurts visibility and makes the use of this touchscreen uncomfortable for many users. By contrast, touchscreen functionality in the lower display has no such problems. It is convenient for the user because the screen is very close to his/her hands and there is no need to raise and hold the arm in the air to actuate the touchscreen. Additionally, the touchscreen oscillation is not an issue because the lower screen can be directly supported by the desk or table the laptop is resting on, and a lever effect inherent in the upper display's edge-proximate connection to the base may be avoided.

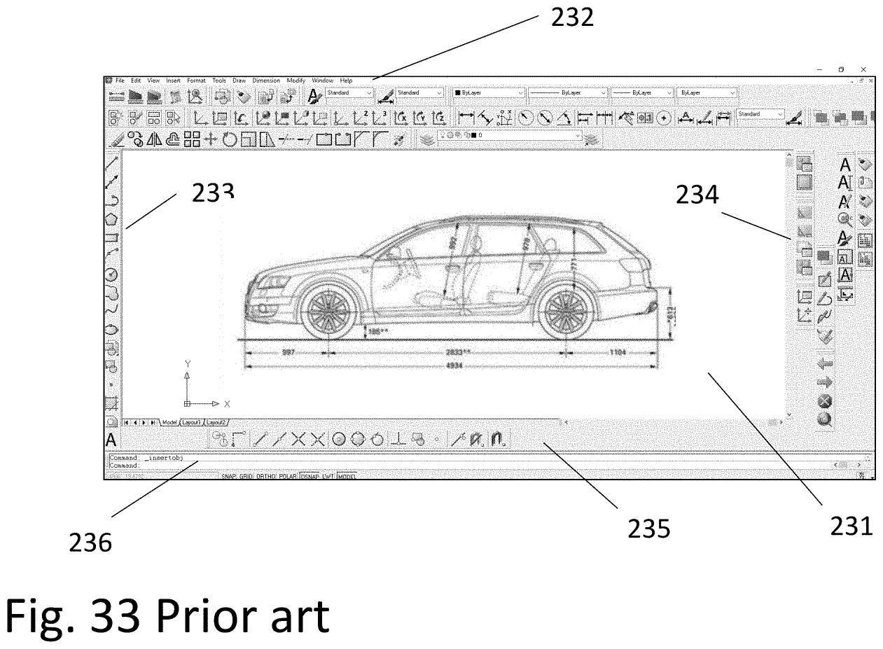

FIG. 33 shows a prior art application from the field of Computer Aided Design (CAD), which will be used to illustrate how the new software methodology of this invention can be used to substantially improve applications in that field. The actual workspace 231 is dramatically reduced in size because of all the ancillary areas that have to be provided for toolbars, options, menus, commands and dialog areas, such as the command and toolbar area 232 at the top of the screen, the drawing toolbar 233 on the left, additional toolbars and formatting tools 234 on the right, an additional toolbar 235 at the bottom and a command entry area 236 at the bottom of the screen. The available workspace area is substantially reduced by the ancillary areas, making it more difficult for the designer to see the actual object being designed (in this example, a vehicle). In addition, a sense of clutter and chaos is created on the screen which can interfere with good design practices, harm productivity, lead to errors and negatively affect the quality of the design being created. Furthermore, the ancillary areas of FIG. 33 are not nearly enough to provide good support to the user, because the amount of information and options available cannot possibly be captured in the ancillary areas. If all necessary commands, options, toolbars, information and support were included in the ancillary areas, there would not be any space left for workspace. Therefore FIG. 33 represents just a very suboptimal compromise. Effective use of such an application requires a very large display screen, thereby inhibiting use of a laptop or portable computer.

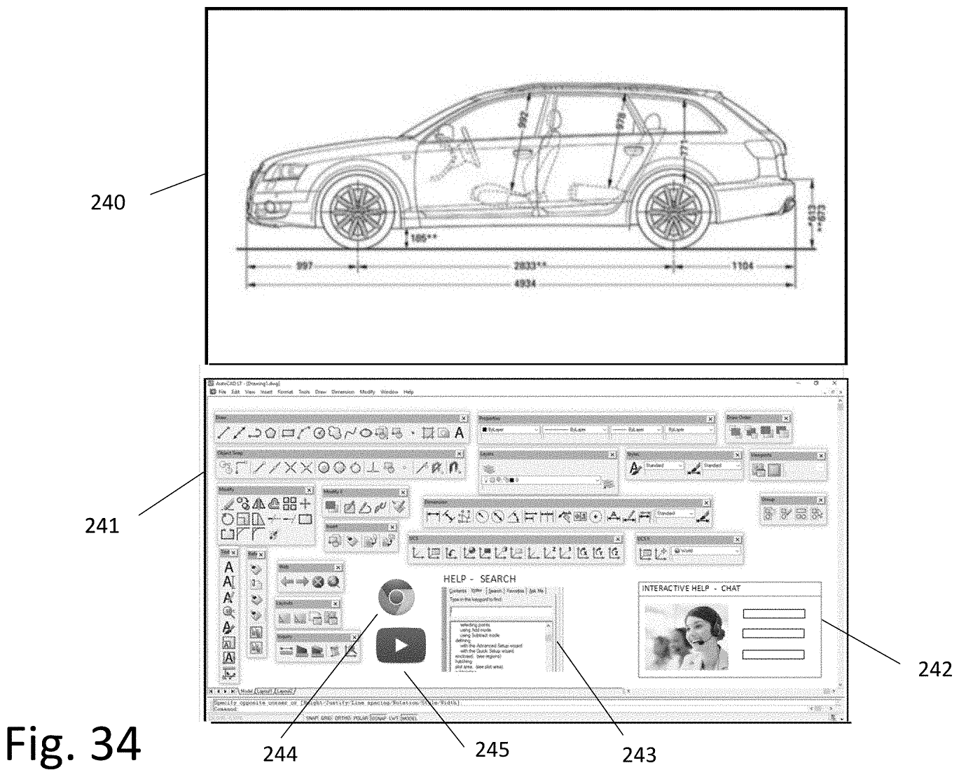

FIG. 34 shows how the new software methodology can dramatically improve the previous CAD application. Display 240 is dedicated primarily to the design object, which therefore can be shown in a large, clear and unobstructed way, enabling higher productivity and better quality design. The second display 241 contains the necessary toolbars, menus, command structures and dialog areas for the user. Because now these toolbars and ancillary areas don't have to compete with the design object for space, substantially more information can be displayed and many more tools, options and customer support facilities can be provided. It is even possible to include an area for a video and/or voice session 242 with a customer service representative or with a knowledge base to support the user as needed. A complete online manual 243 or other help facilities can be made available online to search for commands, features or issues the user may need help with. These help facilities create a level of unprecedented user-friendliness for the app, because the user can see the help facilities on one screen and the app with his design object on the other screen at the same time. Help facilities already exist in the prior art, but their usefulness is limited by the fact that the users has to choose what to see: either the help facility or the design object, not both at the same time. That requires trying to memorize or write down complicated and long sequences of commands or instructions, which is cumbersome, time consuming and often impractical.

FIG. 34 also shows in the lower display 241 by way of example a Google icon 244 and a Youtube icon 245. With icon 244 the user can perform a search for an item relevant to his work on the upper display, and read the search results information on the lower display 241 while his work object on the upper screen remains visible, without having to take notes or try to memorize the search results information. Similarly, with icon 245, the user can play a Youtube video that explains a feature or a procedure needed for his/her work, stopping and restarting the video it as needed to simultaneously apply the information learned to the work in the upper screen. These two icons are just examples of the many possibilities to provide support to the user on one screen and allow him/her to simultaneously apply the information step by step in the other screen.

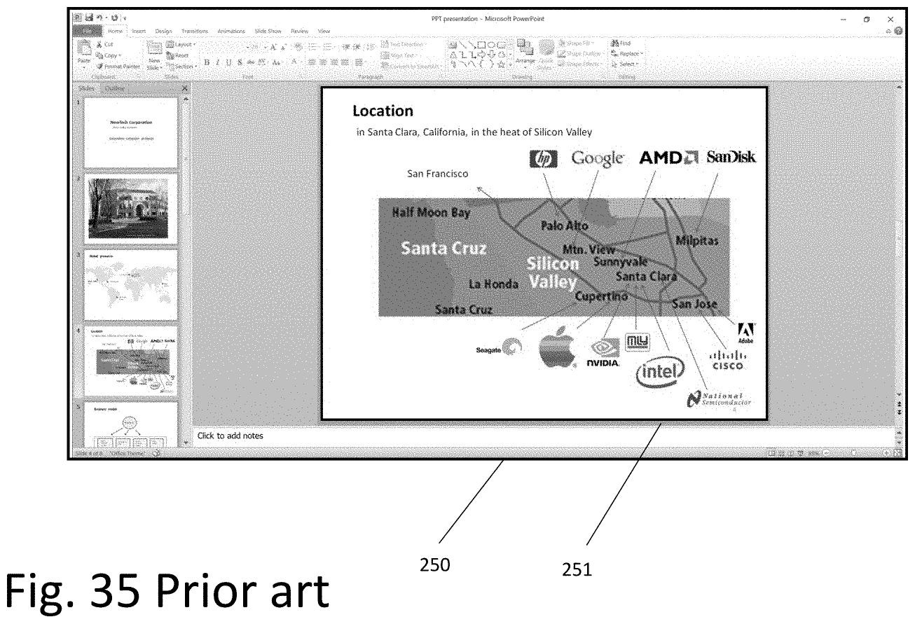

FIG. 35 shows another embodiment of the present invention, illustrating how the new software methodology can be applied in the field of office tools, like word processing, spreadsheets, presentation slides and others. The example shown in FIG. 35 is in the area of presentation software, but the software methodology applies to all office software tools, not just presentation software. The total available screen area 250 is substantially reduced to the rectangle 251, which is the actual presentation slide. A very large part of the display area has to be used for menus and navigation controls. As a result, the slide that the user can see on the screen becomes very small and the user has to work on the slide by constantly zooming into portions of it, which causes loss of context and makes it hard to design a well-organized and attractive, readable and effective slide. The user has to be constantly zooming in and out to create or modify a slide because the slide does not fit into the available workspace in a readable size.

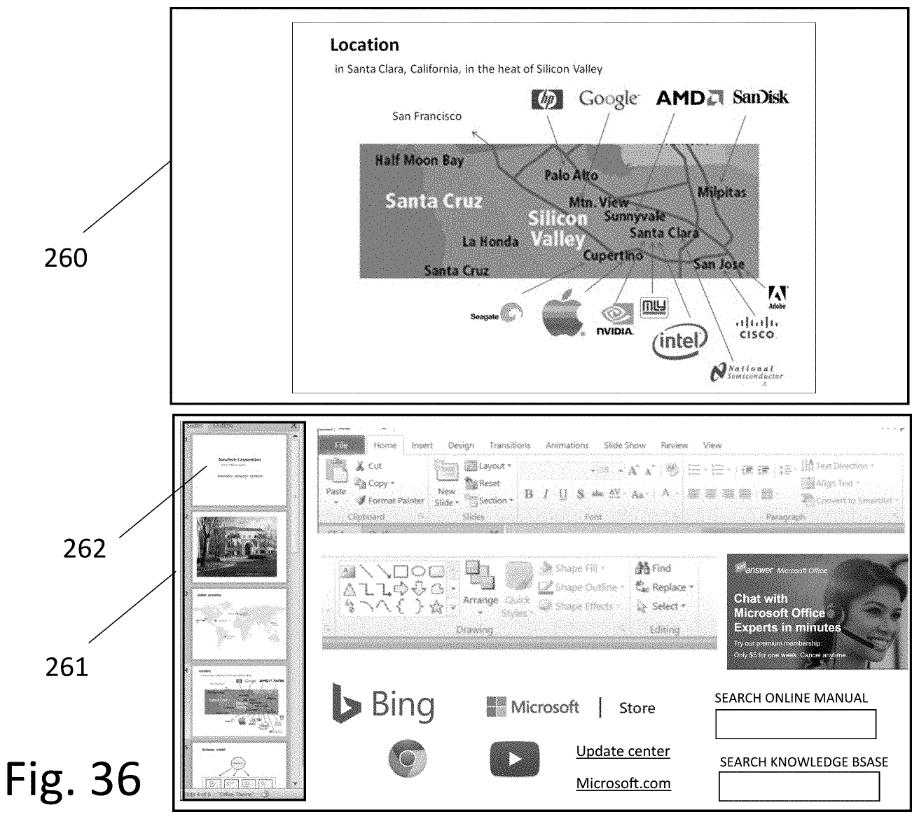

FIG. 36 shows that display 260 is primarily used as workspace for the slide being created, which can be displayed in a much larger size with better readability. The slide is not obstructed and obfuscated by menus, toolbars and other ancillary areas. Display 260 basically is a large, very clean and clear slide, which is conducive to higher productivity, better user experience, better visualization of the slide in full size and full context, and ultimately a higher quality slide. The second display 261 is used for all menus, toolbars, command lines, dialog areas and communication with the user. The larger availability of space for those purposes now makes it possible to have more user-friendly menus and structures. The software designer does not have to be as cryptic as before in an effort to save every square mm of available space for ancillary areas. It is also possible to offer on-line manual search, online knowledge base search, online support with an expert, ability to share the second screen with a remote customer service specialist to debug a problem, conduct a web search while still having the slide visible on the first display, ability to view a YouTube video or a tutorial about an issue or a procedure while the slide being created remains visible on the first display, and many other (update center, download center, online chat, knowledge base access, etc.). The abundance of toolbars, menus, options and support resources that can be made available to the user without leaving the app (which can remain all the time visible on the first display) can dramatically improve user-friendliness, user experience and productivity.

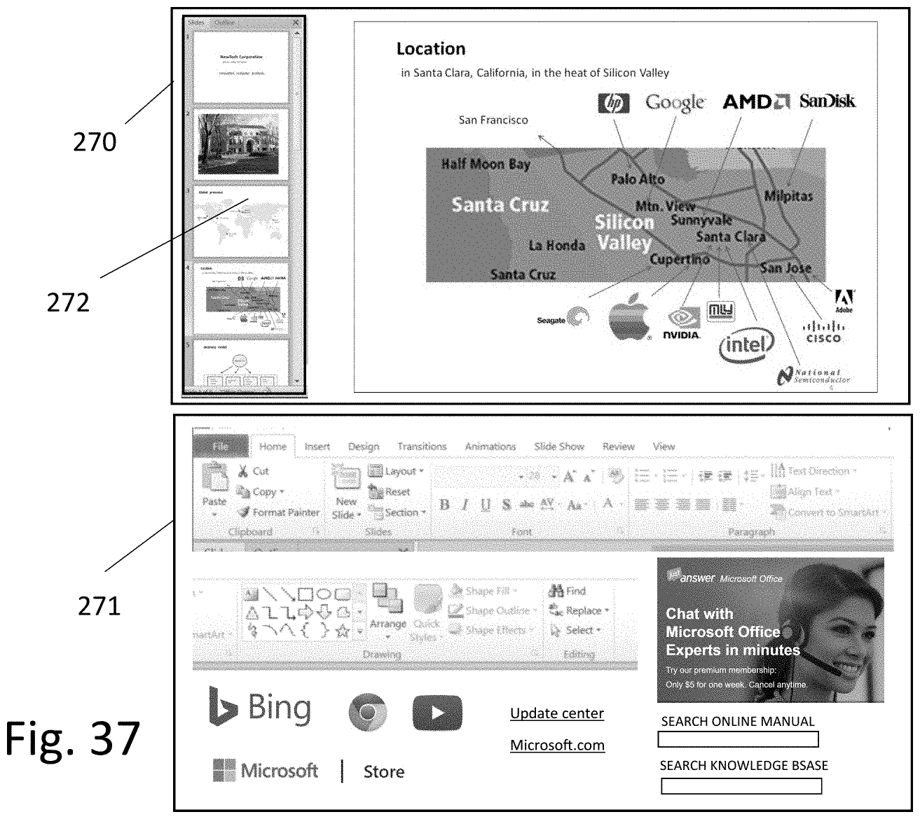

FIG. 37 shows a variation of the previous embodiment, wherein screen 270 retained the slide navigation bar 272. It is shown here to clarify that some ancillary areas can remain with the workspace in the same display, if that makes sense for the user. It is generally a good idea to decongest display 270 and move all or most of the ancillary areas to display 271, but exceptions of course are warranted if they make sense for the user. In addition, the mouse should keep the ability to invoke and trigger many functions and commands that users like to have at short range.

Numerous other embodiments are possible that can provide a dramatically better user experience and/or higher productivity and/or other benefits. Some of these embodiments are described below.

Another embodiment is multi-screen laptop-based advertising, wherein all or part of one of the displays is used to show advertising, which can be distracting and annoying to users in the main screen, but more tolerable on a second screen. An example of this is in the area of advertising-funded software, where the user gets the software for free or for a reduced price in exchange for agreeing to ads being shown on the screen. Those ads can be displayed on the second display, which also has the advantage that the user is less likely to immediately skip the ads since on a second display they are not as disruptive to the user as on the main screen. The ads area on the second display can also be made permanent, non-skippable by the user.

Another embodiment is multi-screen laptop-based gaming software, wherein the user can enjoy a full, uncluttered screen for the actual game and a second screen for game statistics, settings and other uses, creating a much better user experience for the gamer. Another gaming embodiment is a gaming software application wherein one player or party is assigned to one screen and a second player or party is assigned to the second screen.

Another embodiment is multi-screen laptop-based video conferencing software, wherein one party can be assigned to one screen and the other party to the other screen. Alternatively, one screen can be used for showing the remote party while the second display is used as a workspace where the parties can show text or images or drawings to share with the other party. Multiples variations are possible, including but not limited to the addition of external monitors, which can be used to show parties or as shared displays.

Another embodiment is multi-screen laptop based education and training, where one of the laptop screens shows the remote instructor and the other screen is used as the teacher's “blackboard”, i.e. the area the instructor uses to write information he wants to communicate to the student/trainee. An alternative approach consists of the instructor using one display for demonstration and teaching, while the student works on the second screen implementing what is being shown on the first screen. Examples of this latter approach are: teaching how to use computer software and hardware, repair and maintenance of mechanical equipment, how to use military equipment, and many other variations.

Another embodiment is multi-screen laptop based sales, with a sales person on one laptop screen and the product/product info on another screen.

Another embodiment of the invention is multi-screen laptop sports presentations, which can show the sports event full-screen on one laptop display, while stats, information, scores, replays, commentaries and advertising are shown on another display.

Another embodiment is multi-screen laptop-based Video Conferencing and Communications. One display shows one of the parties, while the other display shows the other party, or alternatively can be used to display relevant information by either party. It is also possible to incorporate a third display at each location, since the present invention supports also external monitors.

Another embodiment is multi-screen based Social Media applications. One display can be used to show primarily one of the parties, while the other display can be used to show primarily the other party or alternatively can be used to display to exchange images, videos, texts or any other type of information. It is also possible to incorporate a third display at each location, since the present invention supports also external monitors.

The preceding embodiments disclose how to use a multi-display software methodology to dramatically improve applications such as CAD and office software including word processing, presentation software, spreadsheets and many others. The invention applies not just to those applications mentioned above. It is also fully applicable to applications such as graphics/photo editing (such as Photoshop), gaming, customer service applications including remote support and screen sharing, training with trainer using one screen to demonstrate and the trainee using the other screen to apply the lessons, and many others.

The previous examples described many of the software applications that can benefit from the software methodology of the present invention. Also very important is a Multi-Screen Operating System (MSOS) that properly supports multiscreen technology and enables the user to take advantage of its multiple benefits. The present invention includes such an MSOS, which is described below.

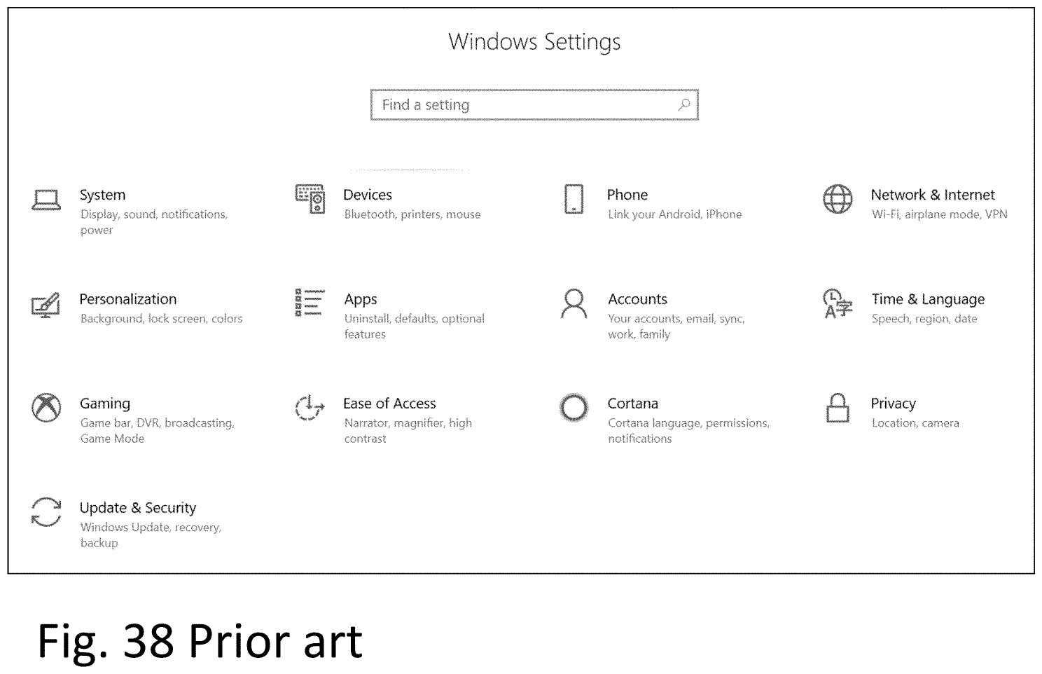

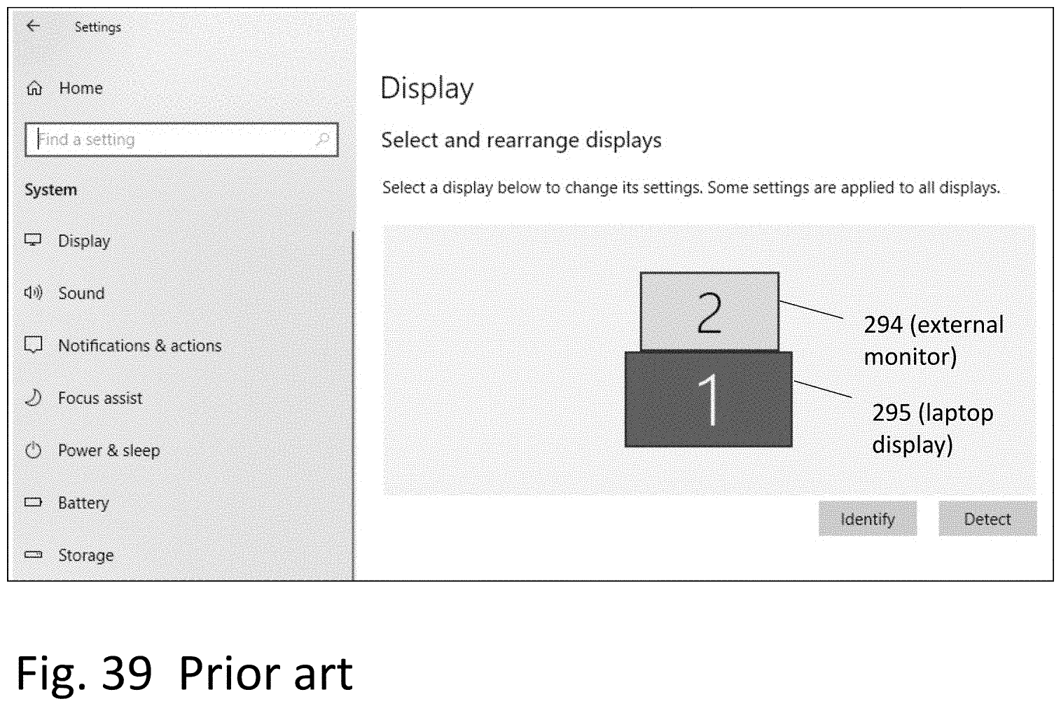

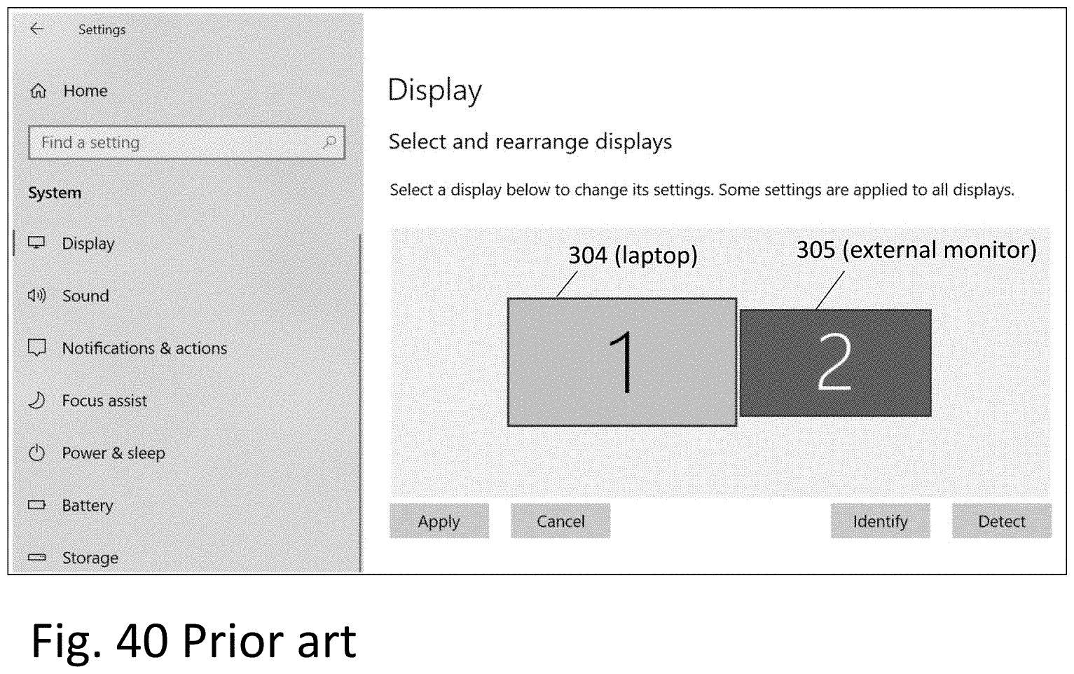

FIG. 38 shows as an example a prior art Operating System (Windows 10 in this chosen example). The settings options in FIG. 38 allow the user to set and configure the laptop and its devices as needed by the user. For instance, if the user enters “display” in the Search box near the top of the screen, then FIG. 39 is shown on the screen. FIG. 39 allows the user to arrange the laptop display 295 (identified as 1) and an external monitor display 294 (identified as 2) in the desired way, by dragging those boxes with the mouse to the desired position. Windows 10 is an operating system designed for single-screen laptops, therefore there is only one laptop screen (shown as display 1). Windows 10 can also support an external monitor (shown as display 2) which is a stand-alone display that sits on the desktop next to the laptop and connects to the laptop through an HDMI interface or through a VGA port or similar. The external display can be physically placed behind the laptop, as shown in FIG. 39, or to the right of the laptop, as shown in FIG. 40, or to the left of the laptop (not shown) or even in front of the laptop (rarely used).

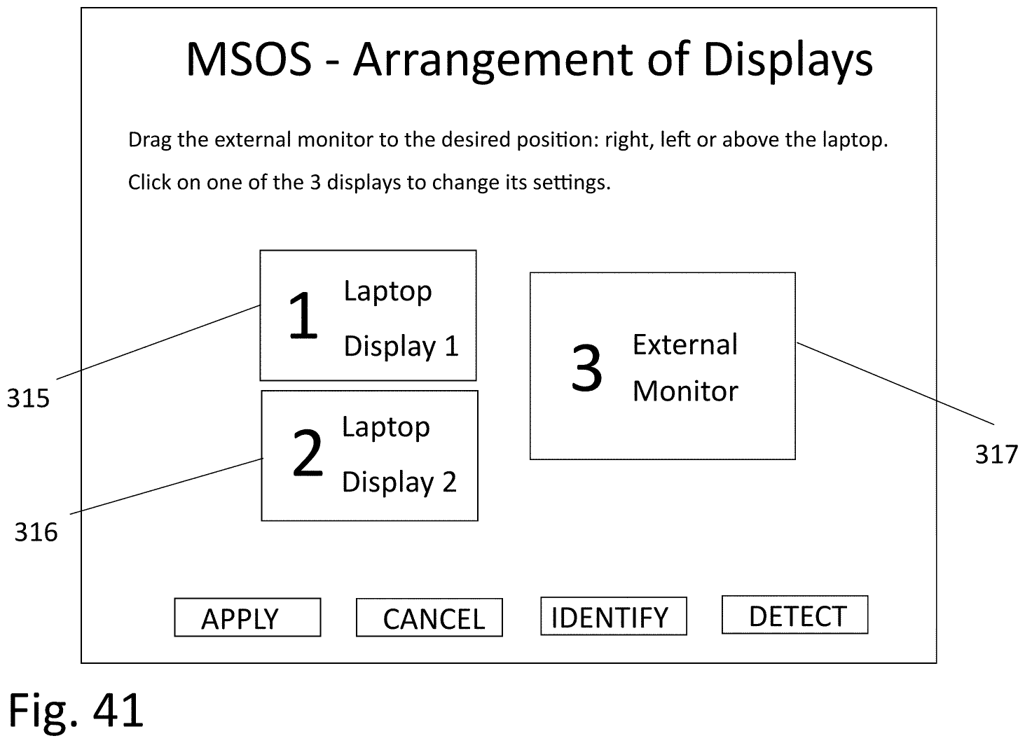

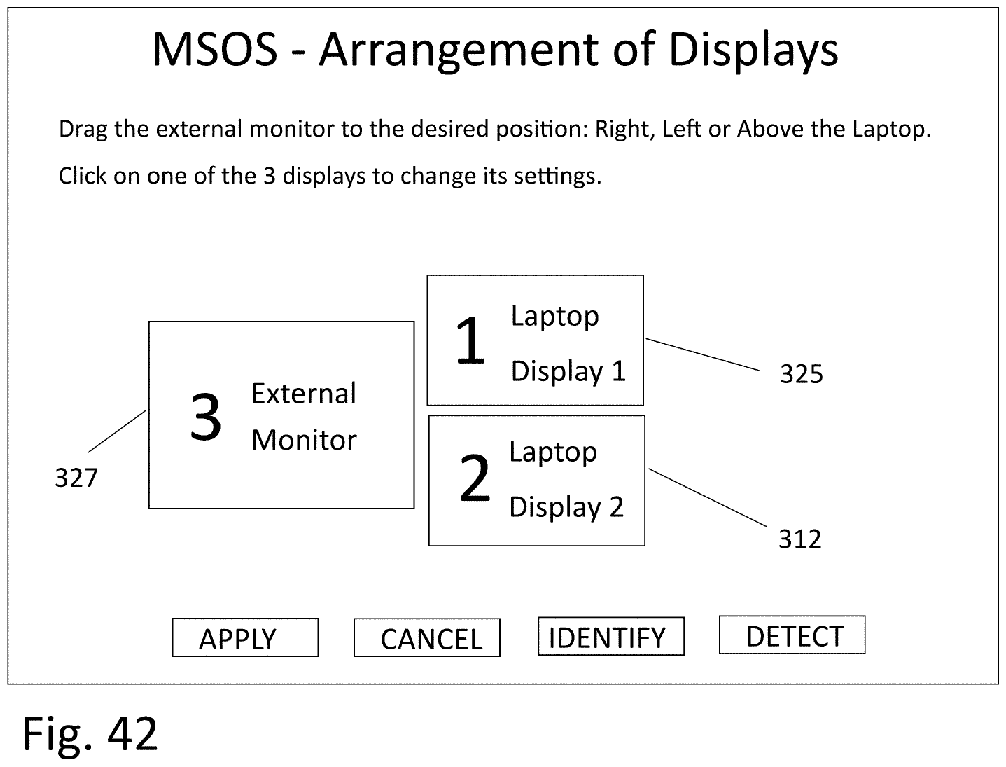

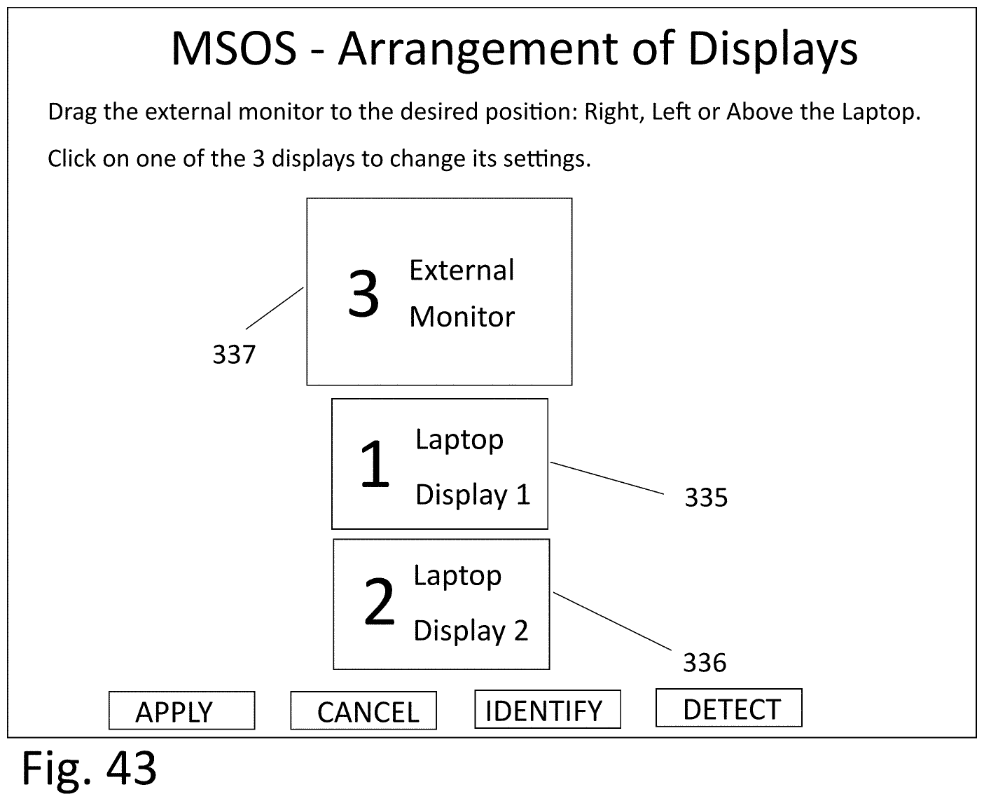

FIG. 41 shows the display position settings in the Multi-Screen Operating System of this invention. Display 1 (identified by numeral 315) and display 2 (identified by numeral 316) are the laptop displays, and their relative position is fixed (the user cannot separate them, because the 2 laptop displays are physically linked by the laptop structure). The External Monitor 317 is shown as Display 3 (identified as numeral 317), and in this example it can be located to the right of the laptop displays (as shown in FIG. 41), or to the left (as shown in FIG. 42) or behind the laptop displays (as shown in FIG. 43). Once the user has chosen the desired arrangement, he/she can confirm it by pressing the Apply button. There are many possible variations of this approach, and this one is described here just as an example, not to limit the invention to this particular graphical approach to define the arrangement of displays. The arrangement of displays is important, because the MSOS will allow the user to select objects or complete windows and move them seamlessly from any one of the 3 displays to any of the 3 displays available (or just 2, if no external monitor is connected). The arrangement of displays will govern how the user needs to move the mouse in order to do that, and the MSOS needs to know the arrangement to correctly interpret the mouse movements.

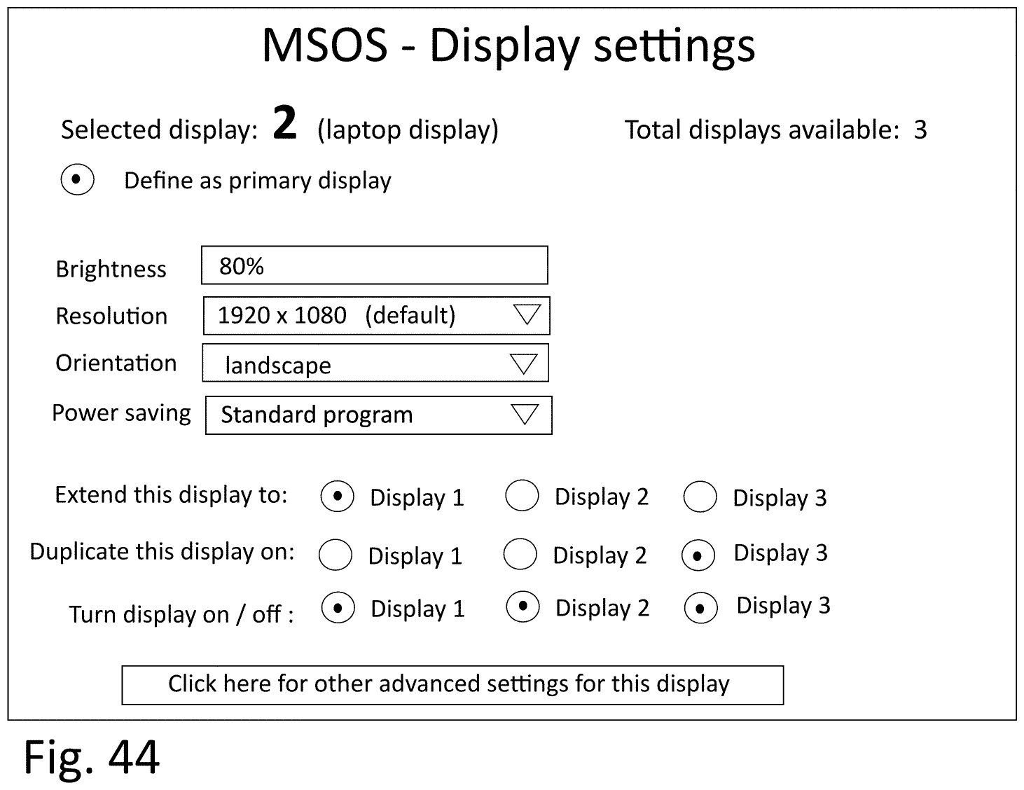

FIG. 43 also shows that the Multi-Screen Operating System of this invention allows the user to select any one of the 3 available screens in order to select it and change its settings. For example, clicking on the box identified as 2 will lead the user to FIG. 44.

FIG. 44 shows the setup screen for display 2, as an example. The user can adjust brightness, resolution and a number of other features and settings. The user can also choose to extend the display from the currently selected display 2 to any other display, or to duplicate (mirror) the currently selected display 2 on any other display.

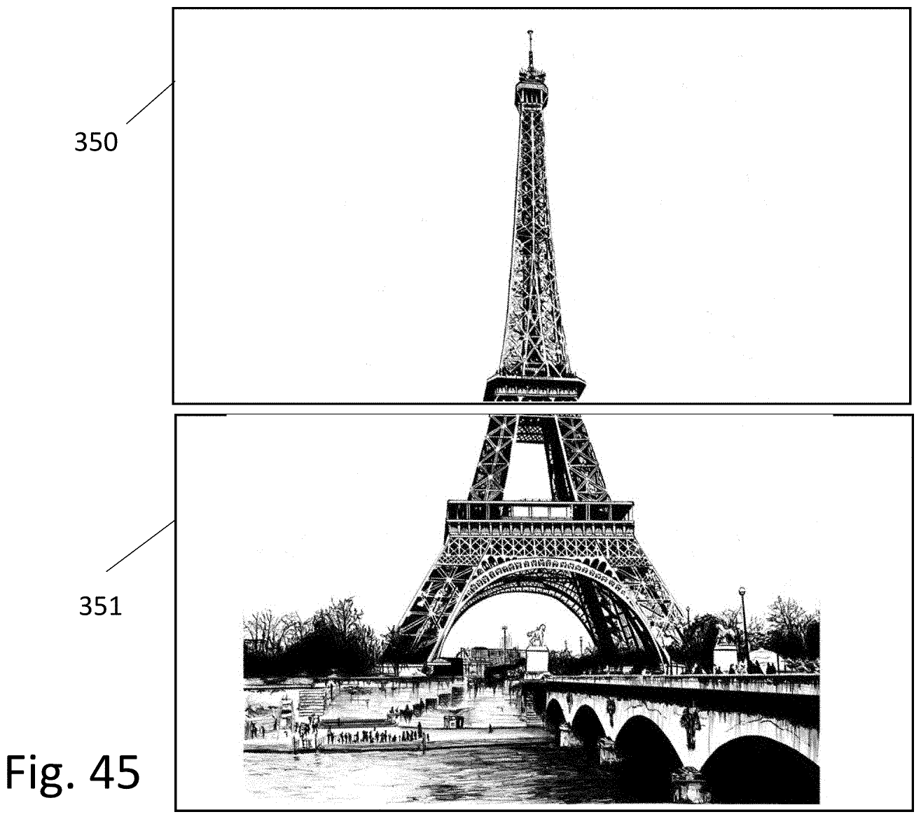

FIG. 45 shows an embodiment that uses the hardware configurations previously shown in FIG. 23 and FIG. 27. In those configurations the two displays can be positioned to be substantially parallel and adjacent to each other, which enables the use of the two displays as one single very large display. Like many of the software features described herein, that capability can be implemented at the application level or at the operating system level. In FIG. 45 the two laptop displays 350 and 351 can be used to show a large integrated image together. The creation of a very large laptop display through integration of two displays is not limited to images, it can also be used to show any large objects, such as large spreadsheets that will not fit on one display, or long logic diagrams, long decision trees, complex organizational charts, large scenarios for gaming software and many others.

The above disclosures and descriptions are exemplary in nature, and not intended to limit the scope of the invention. A person skilled in the art given the present disclosures could easily design variations and additional embodiments of the same invention based on these disclosures, which are all covered by the present application for letters patent.

What is claimed:

1. A multiscreen laptop computer comprising:
A laptop base unit;
a first display unit which is rotatably attached to the laptop base unit via a first set of one or more hinges located proximate an edge of the base unit furthest from a user of the computer, wherein said hinges enable adjustment of a user viewing angle for said first display unit; and
a second display unit which is rotatably attached to the laptop base unit via a second set of one or more hinges located proximate an edge of the base unit closest to the user of the computer, wherein said hinges enable the user to adjust a user viewing angle for said second display unit.

2. The multiscreen laptop computer of claim 1, further comprising:
a support structure behind the second display unit, which may be interposed between the second display unit and the laptop base unit to support the second display unit in a position wherein an edge of the second display unit further from the laptop user is elevated from the base unit.

3. The multiscreen laptop computer of claim 1, further comprising a support structure extending between a portion of the second display unit spaced apart from the second set of one or more hinges, and a portion of the laptop base spaced apart from the second set of one or more hinges.

4. The multiscreen laptop computer of claim 3, in which the second display unit comprises a touch-sensitive display.

5. The multiscreen laptop computer of claim 4, further comprising a microprocessor executing software implementing a virtual keyboard on the second display unit.

6. The multiscreen laptop computer of claim 5, wherein the virtual keyboard comprises a plurality of touch-sensitive key areas rendered on the second display that are bordered by touch-insensitive portions of the second display unit, the touch-insensitive portions separating the touch-sensitive key areas from one another.

7. The multiscreen laptop computer of claim 1, further comprising an incline mechanism comprising a support structure that may be deployed by the user between the laptop base unit and a surface on which the laptop may be rested, in order to incline the laptop base unit relative to the surface, the support structure comprising a support structure position adjustment mechanism located within the laptop housing when the incline mechanism is in non-deployed state.

8. The multiscreen laptop computer of claim 7, in which the support structure is continuously adjustable within a range of positions.

9. The multiscreen laptop computer of claim 7, in which the incline mechanism is integrated within a base unit D-panel.

10. The multiscreen laptop computer of claim 9, in which the D-panel further comprises a stylus compartment.

11. A multi-screen laptop computer comprising:
A laptop base unit;
a physical keyboard set within the laptop base unit, proximate an edge of the base unit closest to a user of the laptop;
a first display unit which is rotatably attached to the laptop base unit via a first set of one or more hinges located proximate an edge of the base unit furthest from a user of the computer, wherein said hinges enable adjustment of a user viewing angle for said first display unit; and
a second display unit which is rotatably attached to the laptop base unit via a second set of one or more hinges located proximate an edge of the base unit closest to the user of the computer, wherein said hinges enable the user to adjust a user viewing angle for said second display unit; and
a deployable support structure behind the second display unit, adjustable between at least a first position wherein the support structure supports the second display unit at an incline relative to the base unit; and a second position wherein the second display unit may be stowed against or within the base unit.

12. The multiscreen laptop computer of claim 11, in which the deployable support structure is continuously adjustable to enable continuous adjustment of an angle of incline of the second display unit relative to the base unit.

13. The multiscreen laptop computer of claim 11, in which the deployable support structure is adjustable to a plurality of discrete positions to vary an angle of incline of the second display unit relative to the base unit

14. The multi-screen laptop computer of claim 11, wherein physical gaps between the first display unit and the second display units are minimized so that both display units can be arranged by the user in a coplanar arrangement with respect to one another, whereby the first display unit and the second display unit may be utilized as a single continuous display.

15. A multi-screen laptop computer comprising:
a laptop computer base unit;
a first display unit which is rotatably attached to the laptop base unit via a first set of one or more hinges located proximate an edge of the first display unit closest to a user of the computer, wherein said hinges enable adjustment of a user viewing angle for said first display unit; and
a second display unit which is rotatably attached to the first display unit via a second set of one or more hinges located proximate an edge of the first display unit furthest from the user of the computer, wherein said hinges enable the user to adjust a user viewing angle for said second display unit;
whereby the first set of hinges may be articulated to incline the first display unit above the laptop base unit and raise the second display unit.

16. The multiscreen laptop computer of claim 15, in which the first set of hinges attaches the first display unit to the base unit proximate an edge of the base unit closest to the user of the computer.

17. The multiscreen laptop computer of claim 16, wherein the first display unit has a surface area approximately equal to a top side of the laptop base unit.

18. The multiscreen laptop computer of claim 17, further comprising a microprocessor executing software implementing a virtual keyboard on the first display unit.

19. The multiscreen laptop computer of claim 15, further comprising an adjustable support structure configurable to extend between a back side of the first display unit and the laptop base unit to support the first display unit in an inclined position relative to the base unit.

20. The multi-screen laptop computer of claim 15, wherein physical gaps between the first display unit and the second display units are minimized so that both display units can be arranged by the user in a coplanar arrangement with respect to one another, whereby the first display unit and the second display unit may be utilized as a single continuous display.

21. The multi-screen laptop computer of claim 15, wherein the first set of one or more hinges allow a range of rotation in excess of 180 degrees, such that the second display unit may be folded such that an edge of the second display unit furthest from the user contacts the base unit and faces away from the user, and the first display unit faces towards the user.

22. The multi-screen laptop computer of claim 15, further comprising a physical keyboard set within a portion of the laptop base unit closer to the user of the computer as compared to the position of the first set of one or more hinges.

23. The multi-screen laptop computer of claim 22, wherein the first set of one or more hinges allow a range of rotation in excess of 180 degrees, such that the second display unit may be folded such that an edge of the second display unit furthest from the user contacts the base unit and faces away from the user, and the first display unit faces towards the user.

24. The multiscreen laptop computer of claim 18, where in the microprocessor is further configured to utilize one of the first display unit or second display unit as an application workspace, and to utilize the other of the first display unit or second display unit for software application controls.
